(19) United States
(12) Patent Application Publication
(10) Pub. No.: US 2011/0310446 A1
(43) Pub. Date: Dec. 22, 2011

(54) Image forming apparatus, color adjustment method, and computer program product

(75) Inventor: Manabu Komatsu, Tokyo (JP)

(73) Assignee: Ricoh Company, Limited, Tokyo (JP)

(21) Appl. No.: 13/067,653

(22) Filed: Jun. 17, 2011

(30) Foreign Application Priority Data
Jun. 21, 2010 (JP) 2010-140726
Apr. 5, 2011 (JP) 2011-083899

(51) Int. Cl. G03F 3/08

(52) U.S. Cl. 358/518

(57) ABSTRACT

An image forming apparatus includes: an image generating unit that reads an original and generates image data; a color-region input unit that inputs a color region subject to color matching in the image data; an object-color calculating unit that calculates an object color to which the color region is matched; a color-adjustment-condition setting unit that sets a plurality of color adjustment conditions on-which output of the object color under an image output condition is within an allowable color difference; a color-conversion-condition changing unit that selects one of the color adjustment conditions on which a color difference occurring in an entire color space is smallest, and that changes a color conversion condition; a color conversion unit that performs color conversion of the image data based on the changed color conversion condition; and an image output unit that outputs the image data subjected to the color conversion.

### CROSS-REFERENCE TO RELATED APPLICATIONS

The present application claims priority to and incorporates by reference the entire contents of Japanese Patent Application No. 2010-140726 filed in Japan on Jun. 21, 2011 and Japanese Patent Application No. 2011-083899 filed in Japan on Apr. 5, 2011.

### BACKGROUND OF THE INVENTION

1. Field of the Invention

The present invention relates to an image forming apparatus, a color adjustment method, and a computer program product for color adjustment.

2. Description of the Related Art

In recent years, there is advanced the development of an image reading device using a contact image sensor (CIS) in which equal-magnification optical systems including a light source are formed in one package as a reading unit. In the image reading device using the CIS, a plurality of compact universal image sensor chips (hereinafter, referred to as “sensor chips”) is aligned in a main scanning direction, and a light reflected from a scanned surface of an original is imaged, and the image being read and then converted into an image signal by each sensor chip. Then, the image reading device using the CIS performs a process of electrically joining the image signals converted by the sensor chips up together, thereby obtaining image information corresponding to an entire scanning line.

In the image reading device using the CIS, when reading a uniform image in the main scanning direction, there occurs an output difference (stepwise unevenness) among the sensor chips due to a variation in spectroscopic characteristic of a color filter of each sensor chip or the like.

Therefore, there are known a technology to adjust gamma characteristics of adjacent sensor chips using a correction circuit and a technology to correct the saturation of an output color near achromatic color, and to show up color unevenness at an image data level. Furthermore, as a technology for color adjustment, for example, in a technology disclosed in Japanese Patent Application Laid-open No. H10-32724, for the purpose of increasing the color matching accuracy in a user environment, when colors of an image on an input device and an image on an output device do not match, a gamut of non-matching color is specified as an object color for correction, and profile information is corrected on the basis of a result of determination by a determining unit which determines and selects content to be corrected.

However, in conventional correction of color unevenness, it is difficult to completely eliminate color unevenness between adjacent sensor chips. Furthermore, to correct color unevenness up to a level where humans recognize no output difference (unevenness) over the whole area, high-accuracy correction on a per-sensor chip basis and strict control of a variation of sensor chips at the stage of manufacture, etc. are required, resulting in a cost increase; therefore, it is hard to be applicable.

Also in correction at an image data level, a method to change a correction factor on a per-image area basis has a problem in continuity at the boundary between image areas; and processing is complicated. Furthermore, even if uniform color adjustment, such as a saturation correction, is performed, it results in a color conversion with the color space distorted, so a color non-matching portion is conspicuous depending on contents of an input image; appearance of color unevenness varies according to characteristics of an input image such as paper and ink and an observation environment of an output image; and therefore, a correction efficiency is decreased.

Furthermore, the color adjustment technology as disclosed in Japanese Patent Application Laid-open No. H10-32724 can match a gamut of non-matching color between devices but can not improve color unevenness within an output image.

### SUMMARY OF THE INVENTION

It is an object of the present invention to at least partially solve the problems in the conventional technology.

According to an aspect of the present invention, there is provided an image forming apparatus, including: an image generating unit that reads an original and generates image data; a color-region input unit that inputs a color region subject to color matching in the image data; an object-color calculating unit that calculates an object color to which the color region is matched; a color-adjustment-condition setting unit that sets a plurality of color adjustment conditions on which output of the object color under an image output condition is within an allowable color difference; a color-conversion-condition changing unit that selects one of the color adjustment conditions on which a color difference occurring in an entire color space is smallest, and that changes a color conversion condition; a color conversion unit that performs color conversion of the image data based on the changed color conversion condition; and an image output unit that outputs the image data subjected to the color conversion.

According to another aspect of the present invention, there is provided a color adjustment method, including: reading an original and generating image data by an image generating unit; inputting a color region subject to color matching in the image data by a color-region input unit; calculating an object color to which the color region is matched by an object-color calculating unit; setting a plurality of color adjustment conditions on which output of the object color under an image output condition is within an allowable color difference by a color-adjustment-condition setting unit; selecting one of the color adjustment conditions on which a color difference occurring in an entire color space is smallest, and changing a color conversion condition by a color-conversion-condition changing unit; performing color conversion of the image data based on the changed color conversion condition by a color conversion unit; and outputting the image data subjected to the color conversion by an image output unit.

According to still another aspect of the present invention, there is provided a computer program product including a non-transitory computer program product having computer-readable program codes embodied in the medium for color adjustment in an image forming apparatus, the program codes when executed causing a computer to execute: calculating an object color to which a color region of image data of a read original is matched; setting a plurality of color adjustment conditions on which output of the object color under an image output condition is within an allowable color difference; selecting one of the color adjustment conditions on which a color difference occurring in an entire color space is smallest and changing a color conversion condition; and performing color conversion of the image data based on the changed color conversion condition.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a block diagram showing a configuration example of an MFP according to a present embodiment;

FIG. 2 is a block diagram showing a configuration example of an input-image processing unit according to the present embodiment;

FIG. 3 is a diagram showing an example of an image-area separation signal according to the present embodiment;

FIG. 4 is a block diagram showing a configuration example of an output-image processing unit according to the present embodiment;

FIG. 5 is a sequence diagram showing an example of copy operation performed by the MFP according to the present embodiment;

FIG. 6 is a diagram showing an example of attribute information decoded in the copy operation;

FIG. 7 is a sequence diagram showing an example of calibration operation performed by the MFP according to the present embodiment;

FIG. 8 is a diagram showing an example of a read pattern for ACC;

FIG. 9 is a diagram showing an example of a correspondence relation between an ACC read value and an ACC output pattern;

FIG. 10 is a diagram showing an example of a correspondence relation between a patch color of the ACC output pattern and a color component of the ACC read value;

FIG. 11 is a diagram showing an example of ACC target data;

FIG. 12 is a diagram showing an example of a correspondence relation between ACC target data and LD data;

FIG. 13 is a diagram showing an example of the LD (input level) data;

FIG. 14 is a diagram showing an example of reference flag data for correction of high density of an ACC target;

FIG. 15 is a diagram showing an example of a correspondence relation between corrected ACC target data and LD data;

FIG. 16 is a diagram showing an example of a ground correction table;

FIG. 17 is a diagram showing an example of a correspondence relation between a ground correction rate and an ACC read value;

FIG. 18 is a conceptual diagram of an example of calculation of a base gamma control point;

FIG. 19 is a sequence diagram showing an example of preview display operation performed by the MFP according to the present embodiment;

FIG. 20 is a diagram showing an example of a concept of color signal processing in the preview display operation and color adjustment operation;

FIG. 21 is a diagram showing an example of a three-dimensional input color space divided into a plurality of unit cubes;

FIG. 22 is a diagram showing an example of the unit cube;

FIG. 23A is a diagram showing an example of one of tetrahedrons into which the unit cube is divided;

FIG. 23B is a diagram showing an example of another one of tetrahedrons into which the unit cube is divided;

FIG. 23C is a diagram showing an example of another one of tetrahedrons into which the unit cube is divided;

FIG. 23D is a diagram showing an example of another one of tetrahedrons into which the unit cube is divided;

FIG. 23E is a diagram showing an example of another one of tetrahedrons into which the unit cube is divided;

FIG. 23F is a diagram showing an example of another one of tetrahedrons into which the unit cube is divided;

FIG. 24 is a diagram showing an example of a rule for determining an interpolation coefficient of each tetrahedron;

FIG. 25 is a diagram showing an example of a correspondence relation between CMYK colors and RGB color components;

FIG. 26 is a sequence diagram showing an example of the color adjustment operation performed by the MFP according to the present embodiment;

FIG. 27 is a flowchart showing an example of a color adjustment process performed by the output-image processing unit according to the present embodiment;

FIG. 28 is a diagram showing an example of a hexahedral bipyramid color system based on the Ostwald color system;

FIG. 29 is a diagram showing an example of conversion equations for converting RGB values of a plurality of object colors into data of an HSL color system;

FIG. 30 is a diagram showing an example where each of components ΔH, ΔS, and ΔL from a reference color 0 is divided into four parts;

FIG. 31 is a diagram showing an example of a color adjustment condition for reducing a difference when a color around achromatic color is an object color;

FIG. 32 is a diagram showing an example of another color adjustment condition for reducing a difference when a color around achromatic color is an object color;

FIG. 33 is a diagram showing an example of another color adjustment condition for correction of hue; and

FIG. 34 is a diagram showing an example of another color adjustment condition for correction of lightness.

### DETAILED DESCRIPTION OF THE PREFERRED EMBODIMENTS

An exemplary embodiment of an image forming apparatus, a color adjustment method, and a computer program product for color adjustment according to the present invention is explained in detail below with reference to the accompanying drawings. Incidentally, in the present embodiment, as the image forming apparatus, a multifunction printer (MFP) having a copy function, a printer function, a scanner function, and a facsimile function is taken as an example; however, the image forming apparatus according to the present invention is not limited to this, and for example, can be a copier. Furthermore, the MFP can have at least two of the copy function, the printer function, the scanner function, and the facsimile function.

### 1. Configuration

First, a configuration of the MFP according to the present embodiment is explained.

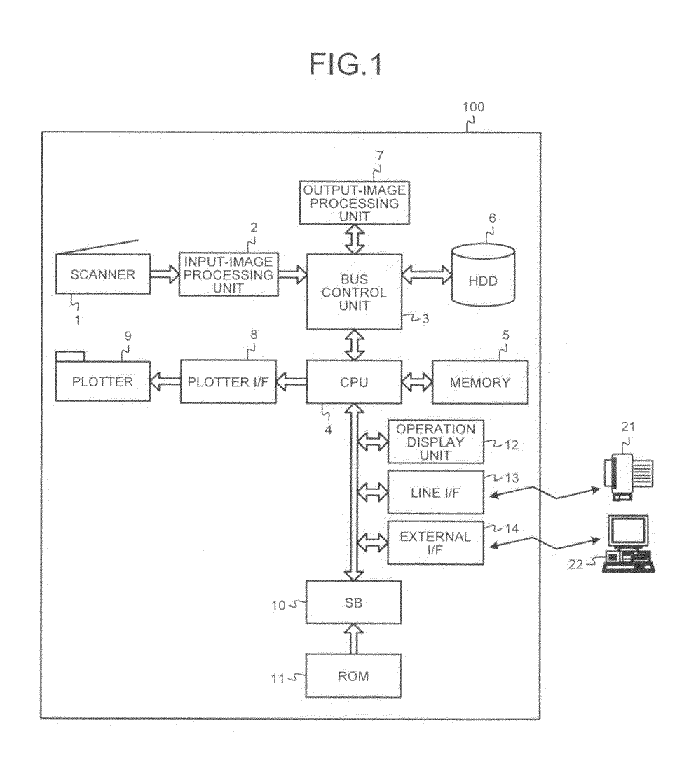

FIG. 1 is a block diagram showing an example of a configuration of an MFP 100 according to the present embodiment. As shown in FIG. 1, the MFP 100 includes a scanner 1, an input-image processing unit 2, a bus control unit 3, a central processing unit (CPU) 4, a memory 5, a hard disk drive (HDD) 6, an output-image processing unit 7, a plotter interface (I/F) 8, a plotter 9, a south bridge (SB) 10, a read-only memory (ROM) 11, an operation display unit 12, a line I/F 13, and an external I/F 14.

The scanner 1 reads an original set in the scanner 1 as computerized image data. Specifically, although not illustrated in FIG. 1, the scanner 1 includes a contact image sensor (CIS), an A/D converter, and a drive circuit for driving the CIS and the A/D converter. The CIS scans the original that is set in the scanner 1 line by line, and the A/D converter generates RGB image data, which is 8-bit digital image data of red (R), green (G), and blue (B) color images, from shading information of the original obtained by the scanning and outputs the generated RGB image data to the input-image processing unit 2.

The input-image processing unit 2 performs image processing on the image data read by the scanner 1 so as to match a predetermined uniform characteristic.

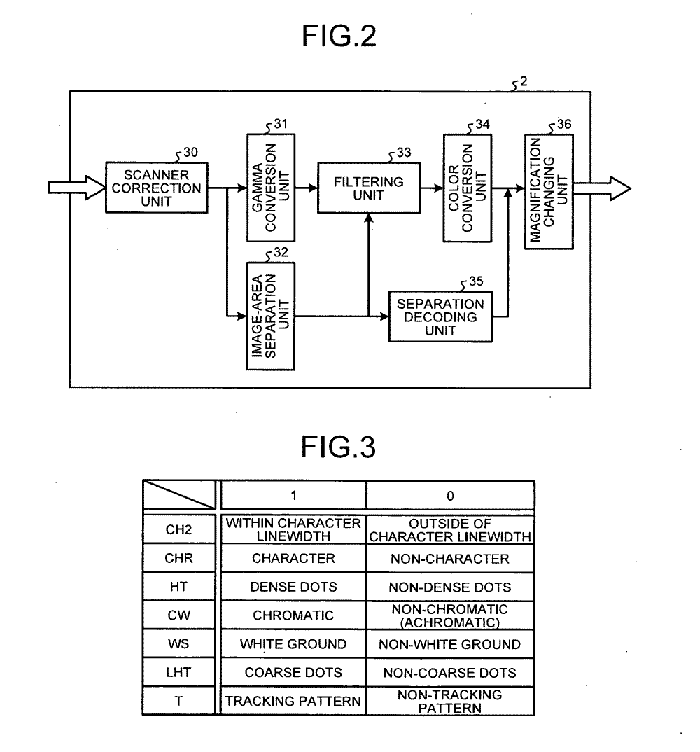

FIG. 2 is a block diagram showing an example of a configuration of the input-image processing unit 2 according to the present embodiment. As shown in FIG. 2, the input-image processing unit 2 includes a scanner correction unit 30, a gamma conversion unit 31, an image-area separation unit 32, a filtering unit 33, a color conversion unit 34, a separation decoding unit 35, and a magnification changing unit 36.

The scanner correction unit 30 performs a scanner correction for correcting shading, such as reading unevenness, caused by the mechanism of the scanner 1 (for example, illuminance distortion or the like) with respect to the RGB image data generated by the scanner 1, and outputs the corrected RGB image data to the gamma conversion unit 31 and the image-area separation unit 32.

The gamma conversion unit 31 performs a gamma conversion for converting a gamma characteristic of the RGB image data subjected to the scanner correction by the scanner correction unit 30 into a predetermined characteristic (for example, 1/2.2 power), and outputs the RGB image data subjected to the gamma conversion to the filtering unit 33.

The image-area separation unit 32 performs an image-area separation for extracting a characteristic area from the RGB image data subjected to the scanner correction by the scanner correction unit 30. Specifically, the image-area separation unit 32 performs extraction of a halftone dot portion formed by general printing, extraction of an edge portion such as characters, determination of whether RGB image data is chromatic or achromatic, and determination of whether a background image is a white background or not, etc. Then, the image-area separation unit 32 outputs a result of the image-area separation as an image-area separation signal to the filtering unit 33 and the separation decoding unit 35.

FIG. 3 is a diagram showing an example of an image-area separation signal output from the image-area separation unit 32 according to the present embodiment. The image-area separation signal shown in FIG. 3 is of 7-bit information composed of seven pieces of 1-bit information, such as “CW” indicating whether RGB image data is chromatic or achromatic and “WS” indicating a result of image-area separation.

Returning to FIG. 2, the filtering unit 33 performs filtering on the RGB image data subjected to the gamma conversion by the gamma conversion unit 31 to match the sharpness of the RGB image data to a predetermined characteristic using the image-area separation signal output from the image-area separation unit 32, and outputs the filtered RGB image data to the color conversion unit 34. Specifically, the filtering unit 33 converts a frequency characteristic of the RGB image data to correct an MTF characteristic of the scanner 1 or prevent moire. As a result, the RGB image data becomes sharp and smooth. For example, when a reference chart (not shown) is scanned, the filtering unit 33 corrects an MTF characteristic value to a value preset with respect to each number of lines per inch (LPI) and each image quality mode.

The color conversion unit 34 performs a color conversion for converting the RGB image data filtered by the filtering unit 33 into RGB image data with a predetermined characteristic, such as sRGB or opRGB, and outputs the RGB image data subjected to the color conversion to the magnification changing unit 36.

The separation decoding unit 35 performs a separation decoding for decoding the image-area separation signal output from the image-area separation unit 32 to attribute information which is information required for processing of the output-image processing unit 7 to be described later, and outputs the attribute information to the magnification changing unit 36. For example, the separation decoding unit 35 decodes the image-area separation signal to 3-bit attribute information representing respective states of black characters, color characters, within the character linewidth, characters on dots, dense dots, coarse dots, a photo, and a tracking pattern or decodes the image-area separation signal to 2-bit attribute information representing respective states of black characters, color characters, within the character linewidth, and non-characters.

The magnification changing unit 36 performs a magnification changing process for changing the size of the RGB image data subjected to the color conversion by the color conversion unit 34 to meet a predetermined uniform characteristic. Incidentally, in the present embodiment, there is described an example where the magnification changing unit 36 converts the size of the RGB image data into 600-dpi image data; however, it is not limited to this. Then, the magnification changing unit 36 outputs the RGB image data of which the size is changed to meet the predetermined uniform characteristic and the attribute information output from the separation decoding unit 35 to the bus control unit 3.

To return to FIG. 1, the bus control unit 3 controls a data bus used for transfer of various data required in the MFP 100, such as image data and a control command, and has a function of a bridge between multiple types of bus standards. In the present embodiment, the bus control unit 3, the input-image processing unit 2, the output-image processing unit 7, and the CPU 4 are connected by a PCI-Express bus and the bus control unit 3; and the HDD 6 are connected by an ATA bus, thereby serving as an application specific integrated circuit (ASIC).

The CPU 4 is a microprocessor that controls the entire MFP 100, and can be realized by, for example, an integrated CPU that various functions are added to a single CPU core. As the integrated CPU, can be used for example, the RMC's RM11100 into which a function of connecting to a general-purpose I/F and a function of connecting between expansion buses using a crossbar switch are integrated. Incidentally, in the present embodiment, the general-purpose I/F is the PCI-Express bus.

Furthermore, the CPU 4 encodes RGB image data, which has been processed by the input-image processing unit 2 so as to meet the predetermined uniform characteristics, and attribute information of the RGB image data or RGB image data transmitted to the external I/F, which has already been processed to meet the predetermined uniform characteristics in advance, and attribute information of the RGB image data, and stores the encoded RGB image data and attribute information in the HDD 6 via the bus control unit 3. Moreover, the CPU 4 decodes the encoded RGB image data and attribute information stored in the HDD 6, and outputs the decoded RGB image data and attribute information to the output-image processing unit 7 via the bus control unit 3.

Incidentally, in the present embodiment, the CPU 4 uses the lossy and high-compression JPEG (Joint Photographic Experts Group) in encoding of the RGB image data and uses the lossless K8 in encoding of the attribute information, thereby minimizing the image degradation.

The memory 5 is a volatile memory used to store therein temporarily-exchanged data to absorb a difference in speed when bridging between multiple types of bus standards or a difference in processing speed of a connected component and temporarily store therein a program and intermediate processing data when the CPU 4 controls the MFP 100. The CPU is required to perform high-speed processing, so the system is booted by a boot program stored in the ROM 11 at the normal start-up, and after that, the CPU performs processing by a program expanded in the high-speed accessible memory 5. Incidentally, the memory 5 can be realized by a dual inline memory module (DIMM) or the like.

The HDD 6 stores therein RGB image data and attribute information which have been encoded by the CPU 4 and the like. Incidentally, the HDD 6 can be realized by a hard disk connected to an ATA bus standardized by extending an IDE. Furthermore, instead of the HDD 6, a nonvolatile storage device, such as a solid state drive (SSD), can be used.

The output-image processing unit 7 performs image processing suitable for an output destination with respect to RGB image data processed to meet predetermined uniform characteristics.

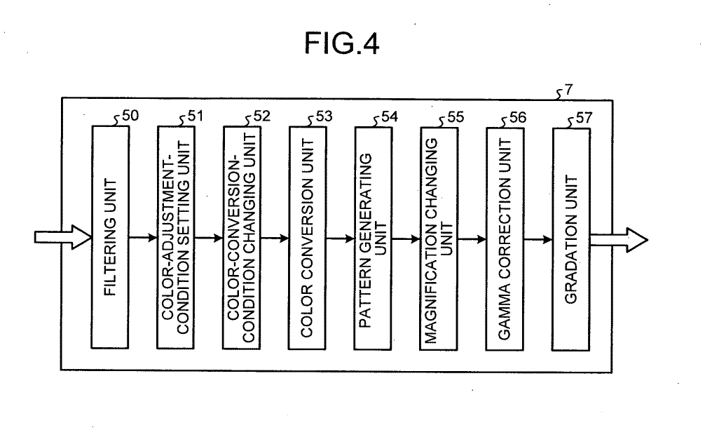

FIG. 4 is a block diagram showing an example of a configuration of the output-image processing unit 7 according to the present embodiment. As shown in FIG. 4, the output-image processing unit 7 includes a filtering unit 50, a color-adjustment-condition setting unit 51, a color-conversion-condition changing unit 52, a color conversion unit 53, a pattern generating unit 54, a magnification changing unit 55, a gamma correction unit 56, and a gradation unit 57.

The filtering unit 50 performs a filtering process for correcting the sharpness of the RGB image data that is processed to meet the predetermined uniform characteristics in accordance with the attribute information so as to improve the reproducibility when the image data is output to the plotter 9.

The color-adjustment-condition setting unit 51 sets a plurality of color adjustment conditions on which output of an object color under an image output condition is come to be within a color allowance at the time of color adjustment operation to be described later.

The color-conversion-condition changing unit 52 selects one color adjustment condition that minimizes a color difference occurring in the entire color space from plurality of color adjustment conditions and changes a color conversion condition at the time of color adjustment operation to be described later.

The color conversion unit 53 performs a color conversion for converting the RGB image data filtered by the filtering unit 50 into a predetermined color space.

The pattern generating unit 54 generates a read pattern for calibration at the time of calibration operation to be described later.

The magnification changing unit 55 performs a magnification changing process for converting the size (resolution) of the image data subjected to the color conversion by the color conversion unit 53.

The gamma correction unit 56 performs a gamma correction on the image data subjected to the magnification changing process by the magnification changing unit 55, using a gamma table set by the CPU 4 in advance.

The gradation unit 57 performs a gradation converting process on the image data subjected to the gamma correction by the gamma correction unit 56.

To return to FIG. 1, the plotter I/F 8 receives CMYK image data transmitted via the general-purpose I/F integrated by the CPU 4, and performs bus bridge processing for outputting the received CMYK image data to the plotter 9. The plotter 9 received the CMYK image data from the plotter I/F 8, and outputs the CMYK image data onto a recording sheet, such as a transfer sheet, by means of an electrophotographic process using a laser beam.

The SB 10 is a general-purpose electronic device having a function of a bridge. The SB 10 is the one that a bridge function of a bus used in building of a CPU system mainly including a PCI-Express bus and an ISA bridge is formed into a general-purpose circuit; and serves as a bridge between the CPU 4 and the ROM 11. The ROM 11 is a nonvolatile memory in which various programs executed by the CPU 4 to control the MFP 100 are stored.

The operation display unit 12 includes a display unit, such as a liquid crystal display (LCD), for displaying thereon various information and an input device, such as a key switch, used for operation input. In the present embodiment, the operation display unit 12 is connected to the CPU 4 via the PCI-Express bus. The operation display unit 12 transmits a command according to an operation input by a user to the CPU 4 via the PCI-Express bus and displays thereon information or a preview image transmitted from the CPU 4 via the PCI-Express bus.

The line I/F 13 is for connecting the PCI-Express bus to a telephone line, and the connection established by the line I/F 13 allows the MFP 100 to transmit/receive image data or the like to/from a FAX 21 via the telephone line. The FAX 21 is a general facsimile machine, and transmits/receives image data or the like to/from the MFP 100 via telephone line.

The external I/F 14 is for connecting the PCI-Express bus to a network such as an Ethernet (registered trademark); and the connection established by the external I/F 14 allows the MFP 100 to transmit/receive image data or the like to/from a personal computer (PC) 22 via the network. The PC 22 is a general computer in which applications and a driver are installed, and transmits/receives image data or the like to/from the MFP 100 via telephone network.

Incidentally, the MFP 100 does not always have to include all the units described above, and some of the units can be omitted from the MFP 100.

### 2. Operation

Subsequently, operation of the MFP according to the present embodiment is explained.

2-1. Copy Operation

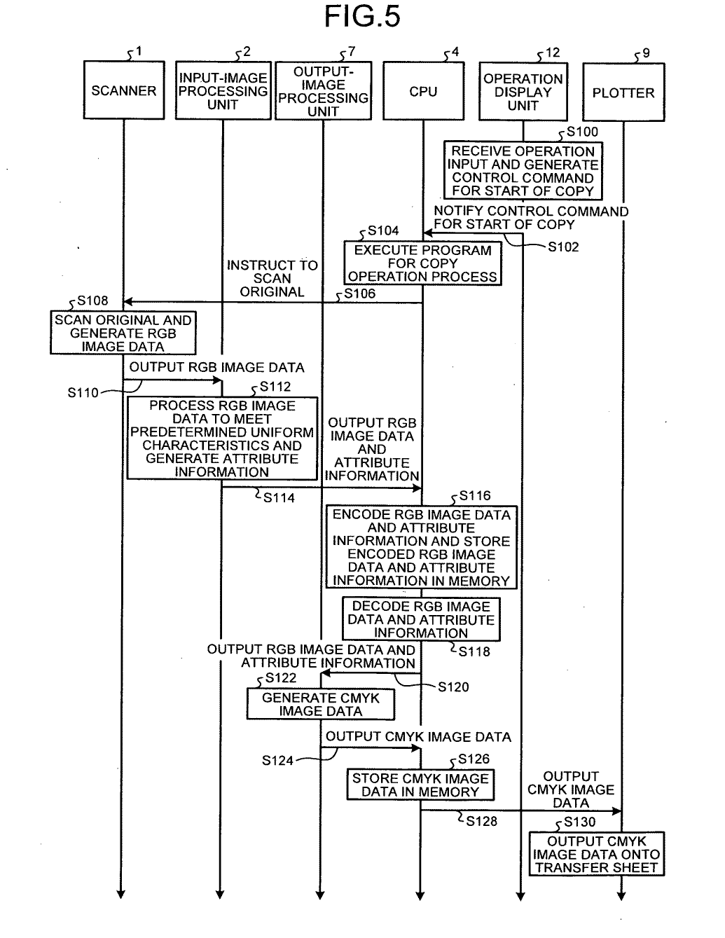

First, copy operation of the MFP according to the present embodiment is explained. FIG. 5 is a sequence diagram showing an example of a flow of procedures of the copy operation performed by the MFP 100 according to the present embodiment.

The operation display unit 12 receives operation input ordering the setting for copy, such as an image quality mode, and operation input ordering the start of copy from a user, and generates a control command for the start of copy (Step S100) and notifies the CPU 4 of the control command (Step S102).

Then, the CPU 4 executes a program for a copy operation process in accordance with the notified control command for the start of copy (Step S104) and performs setting and processing required for the copy operation, such as setting of an image quality mode, and then instructs the scanner 1 to scan an original (Step S106).

Then, the scanner 1 scans the original that is set in the scanner 1 and generates RGB image data (Step S108), and outputs the generated RGB image data to the input-image processing unit 2 (Step S110).

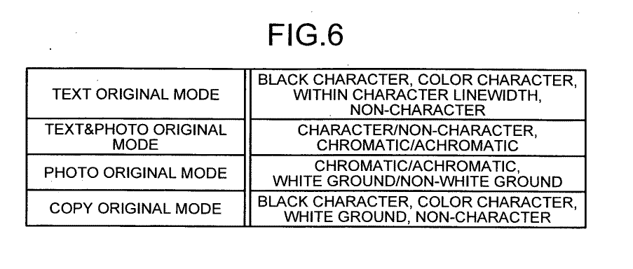

Then, the input-image processing unit 2 performs a scanner correction process, a gamma conversion process, a filtering process, and a color conversion process on the RGB image data to convert the RGB image data into an RGB signal with predetermined uniform characteristics, such as sRGB or ROMM-RGB. Furthermore, the input-image processing unit 2 decodes an image-area separation signal generated by performing image-area separation on the RGB image data into attribute information with respect to each pixel according to the image quality mode set by the CPU 4 (Step S112). For example, the input-image processing unit 2 (the separation decoding unit 35) decodes an image-area separation signal as shown in FIG. 3 into 2-bit attribute information as shown in FIG. 6 according to the image quality mode set by the CPU 4. Then, the input-image processing unit 2 outputs the RGB image data processed to meet the predetermined uniform characteristics and the attribute information to the CPU 4 via the bus control unit 3 (Step S114).

Then, the CPU 4 encodes the RGB image data and the attribute information and stores the encoded RGB image data and attribute information in the memory 5 (Step S116), and decodes the RGB image data and attribute information stored in the memory 5 (Step S118) and outputs the decoded RGB image data and attribute information to the output-image processing unit 7 via the bus control unit 3 (Step S120).

Then, the output-image processing unit 7 performs a filtering process by the filtering unit 50, a color conversion by the color conversion unit 53, a magnification changing process by the magnification changing unit 55, a gamma correction by the gamma correction unit 56, and a gradation converting process by the gradation unit 57 with respect to the RGB image data in accordance with the attribute information, and generates CMYK image data (Step S122).

Specifically, the filtering unit 50 corrects the RGB image data in accordance with the attribute information so as to improve the reproducibility when the image data is output to the plotter 9. For example, in a text original mode, a sharpening process is performed on the RGB image data to make characters clear and sharp; in a photo mode, a smoothing process is performed on the RGB image data to achieve the smooth gradation expression. The color conversion unit 53 converts the RGB image data filtered by the filtering unit 50 into four 8-bit CMYK image data in the CMYK color space for the plotter 9. At this time, the color conversion unit 53 performs optimum color adjustment in accordance with the attribute information. The magnification changing unit 55 converts the size of the CMYK image data subjected to the color conversion by the color conversion unit 53 in accordance with the reproducibility of the plotter 9. However, in the present embodiment, the reproducibility of the plotter 9 is output at 600 dpi, so the magnification changing unit 55 does not perform the conversion. The gamma correction unit 56 performs a gamma correction on the CMYK image data subjected to the magnification changing process by the magnification changing unit 55 by performing a table conversion with respect to each of CMYK color plates using an edge gamma table for CMYK and a non-edge gamma table for CMYK which are set for plotter output by the CPU 4. The gradation unit 57 performs a gradation converting process according to the gradation processing capability of the plotter 9 with respect to the CMYK image data subjected to the gamma correction by the gamma correction unit 56. Incidentally, in the present embodiment, the gradation unit 57 performs the conversion with respect to each 2-bit data of the CMYK image data using an error diffusion method, one of pseudo halftone processing.

Then, the output-image processing unit 7 outputs the generated CMYK image data to the CPU 4 via the bus control unit 3 (Step S124).

Then, the CPU 4 stores the CMYK image data in the memory 5 (Step S126), and outputs the CMYK image data stored in the memory 5 to the plotter 9 via the plotter I/F 8 (Step S128).

Then, the plotter 9 outputs the CMYK image data onto a transfer sheet and produces a copy of the original (Step S130).

Incidentally, although detailed description is omitted, the MFP according to the present embodiment can perform copy/storage operation, i.e., performs the copy operation and storage operation for storing image data used in copy in the MFP at the same time. Furthermore, although detailed description is omitted, the MFP according to the present embodiment can execute first faxing operation for faxing image data of an original read by the scanner. Moreover, although detailed description is omitted, the MFP according to the present embodiment can execute second faxing operation for faxing image data stored in the HDD through the copy/storage operation or printer/storage operation, etc. Furthermore, although detailed description is omitted, the MFP according to the present embodiment can execute first distribution operation for distributing image data of an original read by the scanner to the outside of the MFP. Moreover, although detailed description is omitted, the MFP according to the present embodiment can execute second distribution operation for distributing image data stored in the HDD through the copy/storage operation or printer/storage operation, etc. to the outside of the MFP.

### 2-2. Calibration Operation

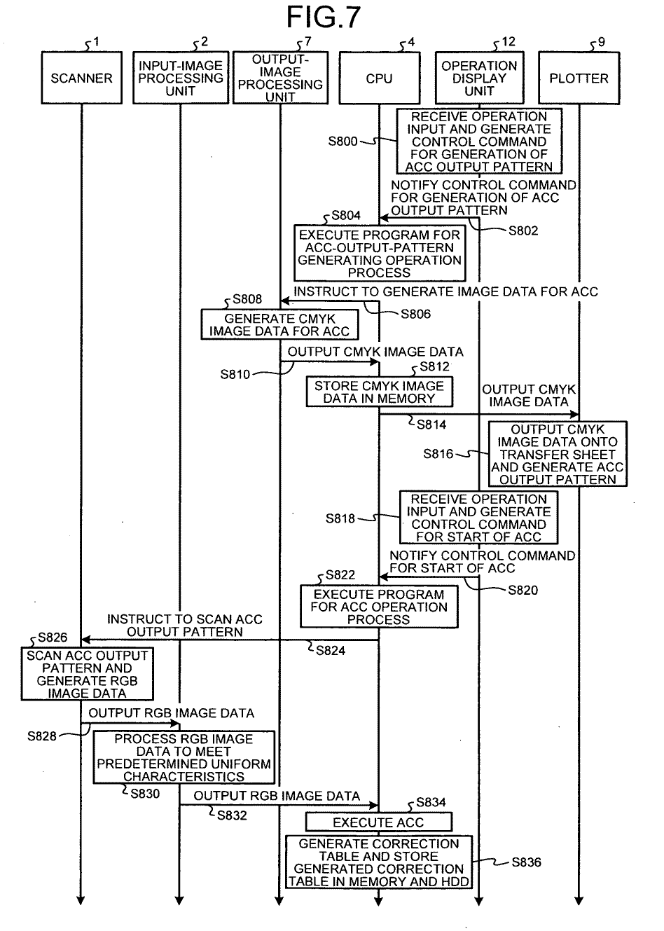

Subsequently, calibration (hereinafter, referred to as “ACC”) operation of the MFP according to the present embodiment is explained. FIG. 7 is a sequence diagram showing an example of a flow of procedures of the ACC operation performed by the MFP 100 according to the present embodiment.

The operation display unit 12 receives operation input ordering generation of an ACC output pattern from a user, and generates a control command for the generation of an ACC output pattern (Step S800) and notifies the CPU 4 of the control command (Step S802).

Then, the CPU 4 executes a program for an ACC-output-pattern generating operation process in accordance with the control command for the generation of an ACC output pattern (Step S804) and performs setting and processing required for the ACC-output-pattern generating operation, such as setting of a mode, and then instructs the output-image processing unit 7 to generate image data for ACC (Step S806).

Then, the output-image processing unit 7 performs generation of a read pattern for ACC by the pattern generating unit 54, a magnification changing process by the magnification changing unit 55, and a gradation converting process by the gradation unit 57, and generates image data (Step S808).

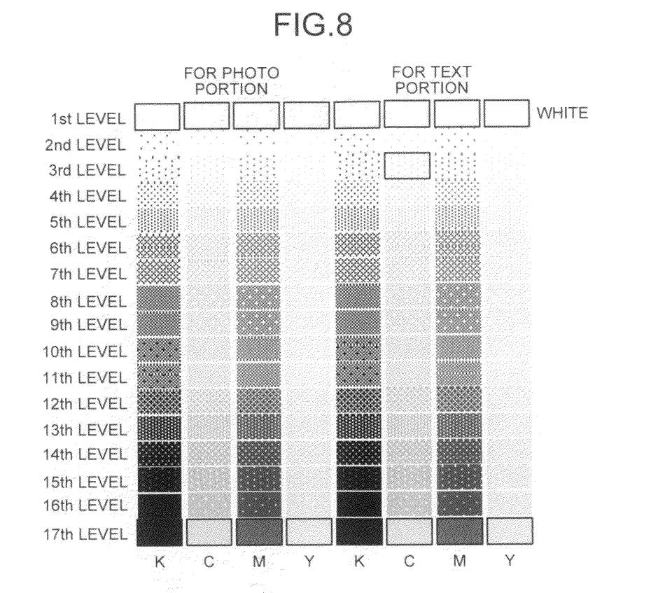

Specifically, the pattern generating unit 54 generates a read pattern for ACC as shown in FIG. 8, which is CMYK image data. The magnification changing unit 55 converts the size of the CMYK image data generated by the pattern generating unit 54 in accordance with the reproducibility of the plotter 9. However, in the present embodiment, the reproducibility of the plotter 9 is output at 600 dpi, so the magnification changing unit 55 does not perform the conversion. The gradation unit 57 performs a gradation converting process according to the gradation processing capability of the plotter 9 with respect to the CMYK image data subjected to the magnification changing process by the magnification changing unit 55 in accordance with attribute information.

Then, the output-image processing unit 7 outputs the generated CMYK image data to the CPU 4 via the bus control unit 3 (Step S810).

Then, the CPU 4 stores the CMYK image data in the memory 5 (Step S812), and outputs the CMYK image data stored in the memory 5 to the plotter 9 via the plotter I/F 8 (Step S814).

Then, the plotter 9 outputs the CMYK image data onto a transfer sheet and generates an ACC output pattern (Step S816).

Then, the operation display unit 12 receives operation input ordering the start of ACC from the user, and generates a control command for the start of ACC (Step S818) and notifies the CPU 4 of the control command (Step S820).

Then, the CPU 4 executes a program for an ACC operation process in accordance with the notified control command for the start of ACC (Step S822) and performs setting and processing required for the ACC operation, such as setting of a mode, and then instructs the scanner 1 to scan the ACC output pattern (Step S824).

Then, the scanner 1 scans the ACC output pattern set in the scanner 1 and generates RGB image data (Step S826), and outputs the generated RGB image data to the input-image processing unit 2 (Step S828).

Then, the input-image processing unit 2 processes the RGB image data to meet predetermined uniform characteristics (Step S830), and outputs the processed RGB image data to the CPU 4 via the bus control unit 3 (Step S832).

Then, the CPU 4 obtains an ACC read value, which is a read value for ACC, from the RGB image data, and performs ACC for changing a target image characteristic (Step S834).

Then, the CPU 4 generates a correction table with reference to the target image characteristic changed through the ACC and stores the created correction table in the memory 5, and also stores the correction table in the HDD 6 via the bus control unit 3 (Step S836).

Here, as an example where the target image characteristic is changed through the ACC, there is described an example where the target image characteristic is changed according to the top density of the image printed out by the plotter 9.

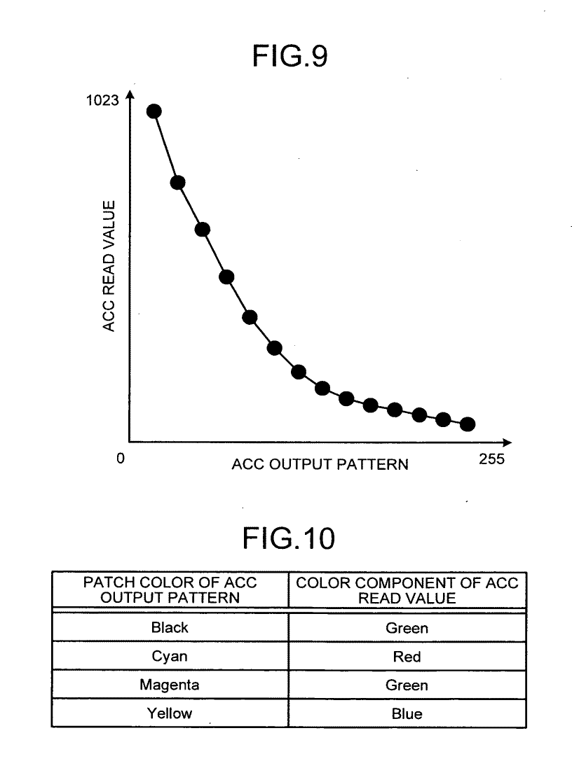

The CPU 4 obtains an ACC read value, which is a read value for ACC, from the RGB image data, and stores a correspondence between the ACC read value and the ACC output pattern as shown in FIG. 9 in the memory 5 as a rawy characteristic. Incidentally, in the present embodiment, for the sake of convenience, an ACC read value corresponding to each ACC output pattern is set as shown in FIG. 10; alternatively, it can be configured to target a plurality of color components.

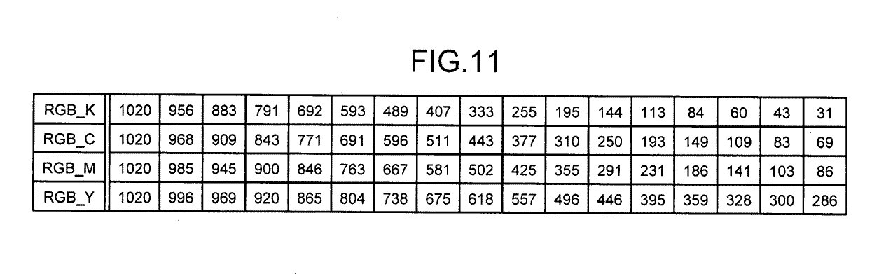

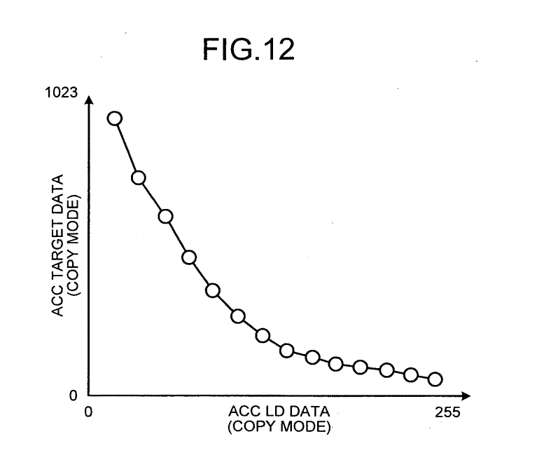

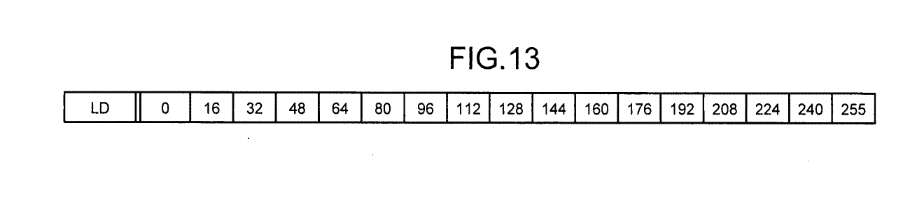

Furthermore, the CPU 4 obtains ACC target data set in an RGB value with respect to each of CMYK as shown in FIG. 11. Incidentally, in an example shown in FIG. 11, 0 to 1 are described as a 10-bit value. Then, as shown in FIG. 12, the CPU 4 tabulates the obtained ACC target data as an ACC target (a read value corresponding to a target output density) characteristic with respect to LD (input level) data (an input level of a CMYK signal) of each color plate as shown in FIG. 13, and stores the table in the memory 5. This ACC target data of each color (CMYK) plate is a target image characteristic of the plotter 9.

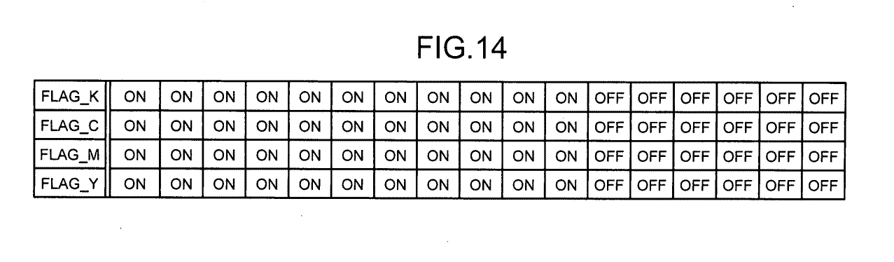

Furthermore, reference flag data for correction of high density of an ACC target as shown in FIG. 14 is defined, and the CPU 4 retrieves a start point of ACC following-property OFF (a point of the lowest density to which the target density is changed according to the top density) and an end point of ACC following-property OFF (a point of the highest density to which the target density is changed according to the top density) from the reference flag data. In the case of examples shown in FIGS. 13 and 14, a value of LD data at the start point of ACC following-property OFF is 176, and a value of LD data at the end point of ACC following-property OFF is 255.

Moreover, the CPU 4 extracts an ACC read value corresponding to the top density of the actual apparatus from the ACC read values.

Here, when ACC target data at the start point of ACC following-property OFF is denoted by ref_max, ACC target data at the end point of ACC following-property OFF is denoted by ref_min, an ACC read value corresponding to the top density (the 16th-level patch corresponding to the top density) is denoted by det_min, an ACC target before ACC target correction of a high density portion is denoted by X, and an ACC target after the ACC target correction of the high density portion is denoted by Y; a correction value of the high density portion is as follows.

When the reference flag data (the following property) is ON, a correction value of the high density portion is obtained by equation (1-1); on the other hand, when the reference flag data (the following property) is OFF, a correction value of the high density portion is obtained by equation (1-2). However, if ref_max is equal to ref_min, Y=ref_max is applied.

Y=X (1-1)

Y=ref_max−(ref_max−X)*(ref_max−det_min)/(ref_max−ref_min) (1-2)

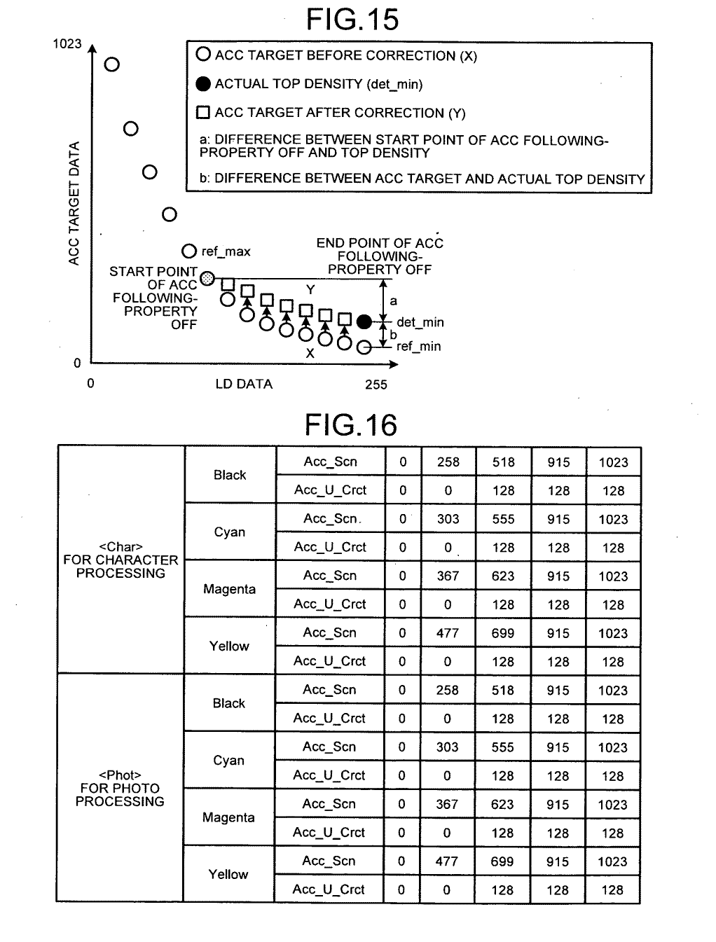

Then, as shown in FIG. 15, the CPU 4 tabulates the corrected ACC target data calculated in this way to be associated with the LD data of each color plate as shown in FIG. 13, and stores the table in the memory 5. Incidentally, in an example shown in FIG. 15, target values between the start point of ACC following-property OFF and the top density are obtained by linear interpolation.

A correction parameter of the high-density portion described above is switched according to a parameter of the following property set by a user through the operation display unit 12, so that the following property of the high-density portion can be changed.

For example, if the top density is low due to a variation of the plotter 9, it is possible to set a parameter increasing a gradation level of following-property OFF so as to reproduce the color with a focus on gradation expression of the high-density portion in a case of outputting a photo image and to set a parameter decreasing a gradation level of following-property OFF in a case of outputting a business graphic image with a focus on reproduction of characters.

This parameter setting enables color adjustment including setting of an image output mode suitable for a state of the actual apparatus and a user request for image output and setting of an optimum calibration condition without repeatedly outputting an image on a recording sheet actually by observing a preview image obtained through preview display operation to be described later thereby recognizing a finished image according to the variable top density of the image forming apparatus.

Subsequently, as another example where the target image characteristic is changed through the ACC, there is described an example where the target image characteristic is changed on the basis of the following property with respect to the ground (paper white).

The CPU 4 obtains an ACC read value, which is a read value for ACC, from the RGB image data, and stores a correspondence between the ACC read value and the ACC output pattern as shown in FIG. 9 in the memory 5 as a rawy characteristic. Incidentally, in the present embodiment, for the sake of convenience, an ACC read value corresponding to each ACC output pattern is set as shown in FIG. 10; alternatively, it can be configured to target a plurality of color components.

Furthermore, the CPU 4 obtains ACC target data set in an RGB value with respect to each of CMYK as shown in FIG. 11. Then, as shown in FIG. 12, the CPU 4 tabulates the obtained ACC target data as an ACC target (a read value corresponding to a target output density) characteristic with respect to LD (input level) data (an input level of a CMYK signal) of each color plate as shown in FIG. 13, and stores the table in the memory 5. This ACC target data of each color (CMYK) plate is a target image characteristic of the plotter 9.

Furthermore, as the rawy characteristic, with respect to the characteristic of ACC read value with the tabulated ACC output pattern as the rawy characteristic, a ground correction table used in calculation of a ground correction rate as shown in FIG. 16 is defined. Incidentally, the ground correction table shown in FIG. 16 is set with respect to each imaging plate of text/photo portions; and Acc_Scn denotes an ACC read value and Acc_U_Crct denotes reference data for correction of the ground. Then, the CPU 4 corrects the ACC read value in the following steps.

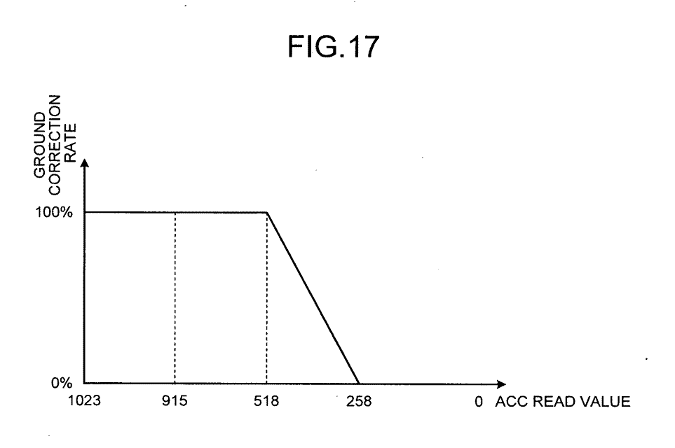

First, the CPU 4 calculates a ground correction rate with respect to an ACC read value. A value of the ground correction rate is calculated by equation (2). For example, taking Black for character processing in the ground correction table shown in FIG. 16 as an example, a ground correction rate with respect to an ACC read value is as shown in FIG. 17. Incidentally, a value that a correction rate between parameters is subject to linear interpolation according to an ACC read value is an actual ground correction rate.

Acc_{—}U_{—}Crct/Basis×100(%) (2)

Incidentally, Basis denotes a reference value of reference data for ground correction, and a default value is set to 128.

Then, the CPU 4 obtains a value of a ground portion (the 0th level) of ACC target data, and calculates a ground correction value of each ACC read value by subtracting the value of the ground portion of the ACC target data from a value of a ground portion (the 0th level) of the ACC read value. When the value of the ground portion of the ACC target data is denoted by Acc_T0, and the value of the ground portion of the ACC read value is denoted by B_Det, Cng_AccT_k denoting a ground correction value of each ACC read value is calculated by equation (3):

Cng_{—}AccT_{—}k=(Acc_{—}T0−B_{—}Det)*Acc_{—}U_{—}Crct_{—}k/Basis (3)

Incidentally, k (0≦k≦16) denotes a correction value of an ACC read value on the k-th level (calculated by linear interpolation).

Then, the CPU 4 corrects the ACC read value by adding Cng_AccT_k denoting a ground correction value of each ACC read value to Acc_Scn_k denoting each ACC read value. Here, Acc_Scn_k′ denoting the corrected ACC read value is calculated by equation (4). Incidentally, the correction is performed on all the ACC read values.

Acc_{—}Scn_{—}k′=Acc_{—}Scn_{—}k+Cng_{—}AccT_{—}k (4)

However, when Acc_Scn_k′ is greater than 1023, Acc_Scn_k′ is clipped to 1023; when Acc_Scn_k′ is a negative value, Acc_Scn_k′ is clipped to 0.

Consequently, if the ground correction rate (up to 100%) is high on the highlight side, color reproduction maintaining a relation with a relative color based on arbitrary paper white recognized as the ground can be achieved; on the other hand, when the ground correction rate (up to 100%) is low, color reproduction faithfully maintaining a tristimulus value CIEXYZ can be achieved regardless of arbitrary paper white recognized as the ground.

Incidentally, the above-described parameter of the following property with respect to paper white can be changed by switching to a parameter set by a user through the operation display unit 12.

This parameter setting enables setting of an optimum calibration condition with respect to a user request and high-quality calibration without repeatedly outputting an image on a recording sheet actually by observing a preview image obtained through preview display operation to be described later thereby faithfully previewing appearance of colors reproduced on various recording sheets.

Subsequently, a method of generating a correction table used by the gamma correction unit 56 of the output-image processing unit 7 by using the ACC target data and ACC read value corrected through the ACC is explained. Here, as a characteristic value with respect to a representative control point which is a reference point of a gamma correction table with respect to an output color (CMYK) from the plotter 9, a base gamma control point is obtained. Incidentally, there are 16 control point input parameters indicating the representative control point which is a reference point of the gamma correction table, and the 16 control point input parameters are 0, 17, 34, 51, 68, 85, 102, 119, 136, 153, 170, 187, 204, 221, 238, and 255.

First, the CPU 4 obtains ACC target data of each control point input parameter. Specifically, the CPU 4 searches which values of LD data between which the control point input parameter is located. When Am, which is the m-th control point input parameter, is found in between LDn−1, which is the (n−1)th LD data, and LDn, which is the n-th LD data, a relation among Am, LDn−1, and LDn can be expressed by LDn−1<Am≦Ldn.

Then, the CPU 4 obtains ACC target data of Am by linearly interpolating corrected ACC target data corresponding to LDn−1; and corrected ACC target data corresponding to LDn. When the corrected ACC target data corresponding to LDn−1 is denoted by Acc_Tn−1, and the corrected ACC target data corresponding to LDn is denoted by Acc_Tn, Acc_Tm′ denoting ACC target data of Am is calculated by equation (5).

Acc_{—}Tm′=((Acc_{—}Tn−Acc_{—}Tn−1)/(LDn−LDn−1))*(Am−LDn)+Acc_{—}Tn (5)

By performing the above process repeatedly with respect to each of the control point input parameters 0 to 255, the CPU 4 obtains respective ACC target data of the control point input parameters.

Then, the CPU 4 obtains an ACC output pattern of each control point input parameter. Specifically, the CPU 4 searches which section of the corrected ACC read value the obtained ACC target data of each control point input parameter is located. When Acc_Tm′, which is the ACC target data of Am, is found in between Acc_Scn_k−1, which is the corrected k-th ACC read value, and Acc_Scn_k−1′, which is the corrected (k−1)th ACC read value, a relation among Acc_Tm′, Acc_Scn_k′, and Acc_Scn_k−1′ can be expressed by Acc_Scn_k′<Acc_Tm′Acc_Scn_k−1′.

Then, the CPU 4 obtains an ACC output pattern of Am by linearly interpolating an ACC output pattern corresponding to Acc_Scn_k′ and an ACC output pattern corresponding to Acc_Scn_k−1′. When the ACC output pattern corresponding to Acc_Scn_k′ is denoted by Acc_Pk, and the ACC output pattern corresponding to Acc_Scn_k−1′ is denoted by Acc_Pk−1, Acc_Pm′ denoting the ACC output pattern of Am is calculated by equation (6).

Acc_{—}Pm′=((Acc_{—}Pk−Acc_{—}Pk−1)/(Acc_{—}Scn_{—}k′−Acc_{—}Scn_{—}k−1′))*(Acc_{—}Tm′−Acc_{—}Scn_{—}k′)+Acc_{—}Pk (6)

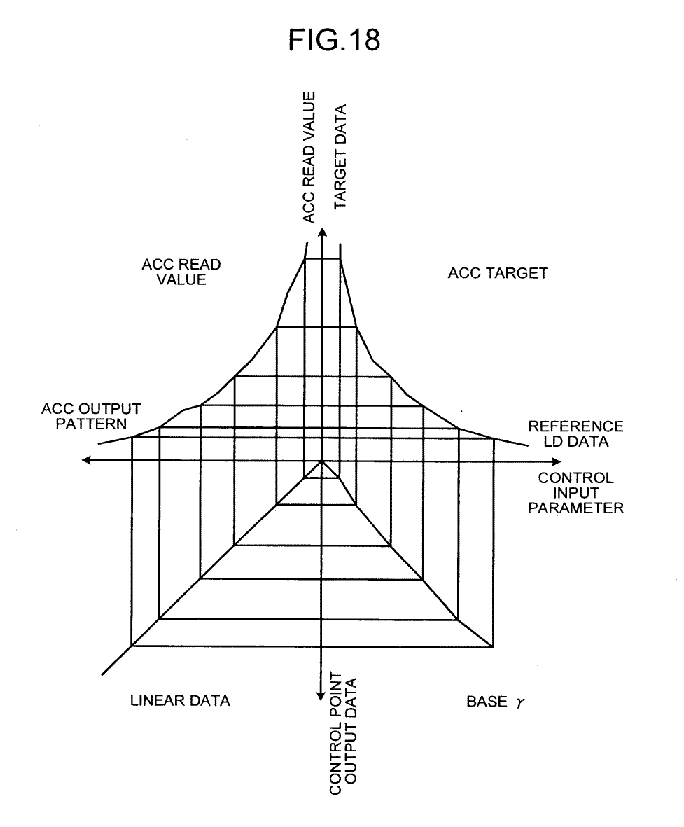

By performing the above process repeatedly with respect to each of the control point input parameters 0 to 255, the CPU 4 obtains respective ACC output patterns of the control point input parameters. The ACC output pattern of each control point input parameter obtained by the CPU 4 is a base gamma control point output parameter. Namely, the correction table shows (control point input parameter, base gamma control point output parameter)=(Am, Acc_Pm′). Incidentally, FIG. 18 shows a conceptual diagram of calculation of a base gamma control point.

### 2-3. Preview Display Operation

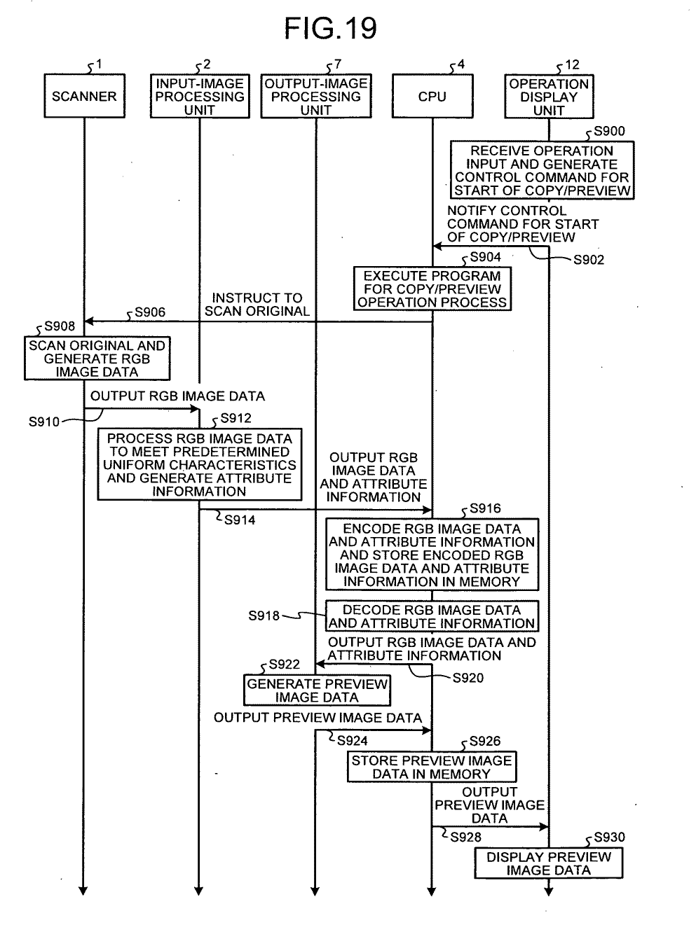

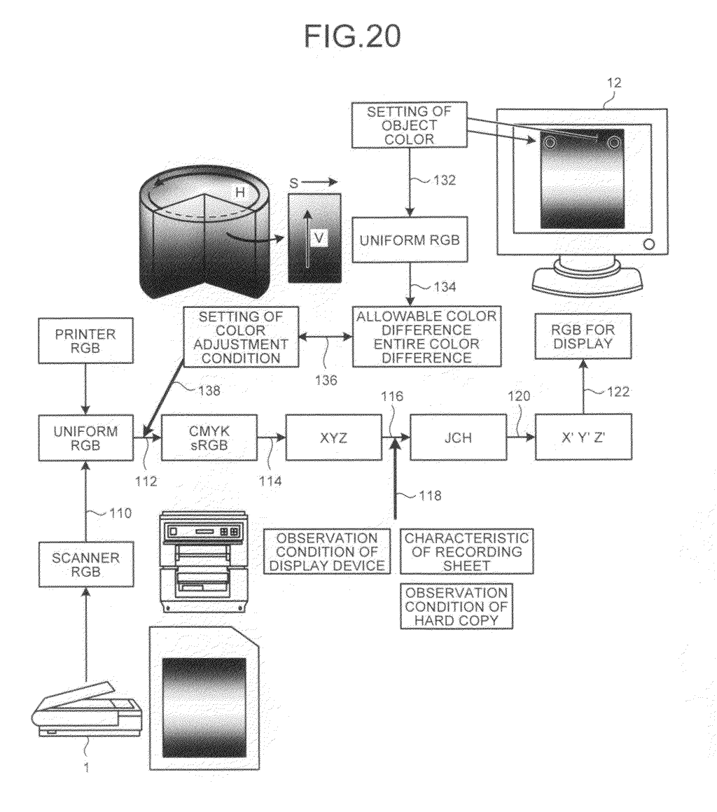

Subsequently, explained is preview display operation of the MFP according to the present embodiment, particularly, operation for converting input RGB, such as printer RGB or scanner RGB, into display RGB that an output color is simulated according to a characteristic of an image output device and an observation condition. Incidentally, in the present embodiment, as the preview display operation, there is described an example where image data of an original scanned by the scanner 1, which will be copied and output by the plotter 9, is previewed; however, the preview display operation is not limited to this example. For example, the preview display operation can be a preview of image data transmitted from the PC 22, which will be printer-output by the plotter 9. FIG. 19 is a sequence diagram showing an example of a flow of procedures of the preview display operation performed by the MFP 100 according to the present embodiment. FIG. 20 is a diagram showing an example of a concept of color signal processing in the preview display operation and color adjustment operation to be described later.

The operation display unit 12 receives operation input ordering the setting for copy, such as an image quality mode, and operation input ordering the start of copy and preview from a user; generates a control command for the start of copy/preview (Step S900); and notifies the CPU 4 of the control command (Step S902).

Then, the CPU 4 executes a program for a copy/preview operation process in accordance with the notified control command for the start of copy/preview (Step S904) and performs setting and processing required for the copy/preview operation, such as setting of an image quality mode, and then instructs the scanner 1 to scan an original (Step S906).

The processes at subsequent Steps S908 to S920 are identical to Steps S108 to S120 of the copy operation shown in FIG. 5. Incidentally, in the color conversion process performed by the input-image processing unit 2, the RGB image data is converted into uniform RGB by means of scanner gamma correction by one-dimensional table conversion or the like and general linear masking operation, etc. (see an arrow 110 in FIG. 20).

Then, the output-image processing unit 7 performs a color conversion by the color conversion unit 53 and a gamma correction by the gamma correction unit 56 on the RGB image data, and generates preview image data for a preview (Step S922), and then outputs the generated preview image data to the CPU 4 via the bus control unit 3 (Step S924).

Then, the CPU 4 stores the preview image data in the memory 5 (Step S926), and outputs the preview image data stored in the memory 5 to the operation display unit 12 (Step S928).

Then, the operation display unit 12 displays the preview image data (Step S930).

Here, the color conversion performed by the color conversion unit 53 of the output-image processing unit 7 is explained specifically.

In a case of plotter output operation, the color conversion unit 53 converts the RGB image data into CMYK image data to meet the output colors of the plotter 9 by performing a three-dimensional LUT conversion or the like (see an arrow 112 in FIG. 20). Incidentally, as a conversion algorithm of the three-dimensional LUT conversion, the widely-used conventional memory map interpolation method can be used.

In the memory map interpolation method, a three-dimensional input color space is divided into a plurality of unit cubes, and each of the unit cubes is further divided into six tetrahedrons sharing the symmetry axis, and then an output value is obtained by linear operation with respect to each unit cube. In the linear operation, data of a grid point, which is a point at the division boundary is used as a parameter (hereinafter, referred to as a “grid-point parameter”). Incidentally, in the present three-dimensional memory map interpolation, the three-dimensional input color space is divided into eight unit cubes, so the length of a side of each unit cube is 32.

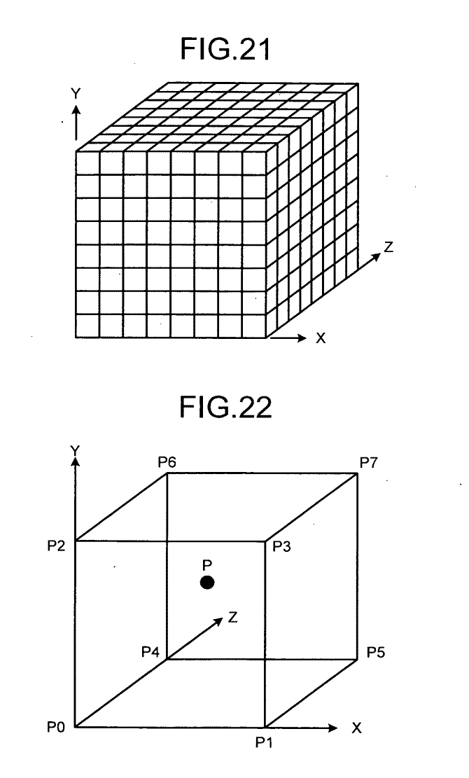

Specifically, as shown in FIG. 21, the color conversion unit 53 divides the three-dimensional input color space in X, Y, and Z directions into (512, in this example) unit cubes by dividing each dimensional surface of the three-dimensional input color space in each direction (into eight, in this example).

Then, the color conversion unit 53 selects one of the unit cubes containing coordinates X(x, y, z) of the input data. Here, the following equality holds true: X(x, y, z)=(In_R, In_G, In_B). FIG. 22 is a diagram showing the selected unit cube, and P0 to P7 denote grid-point output values equivalent to device CMYK of the plotter corresponding to the RGB colors.

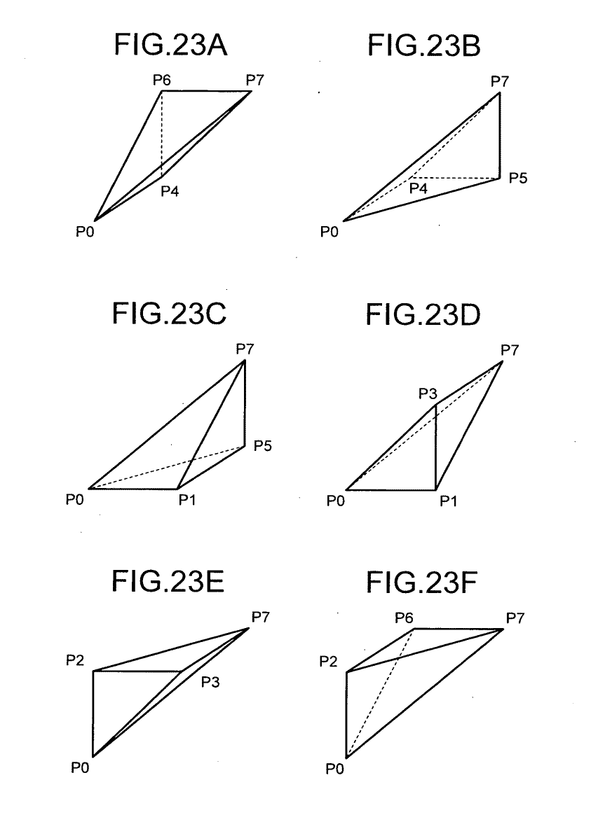

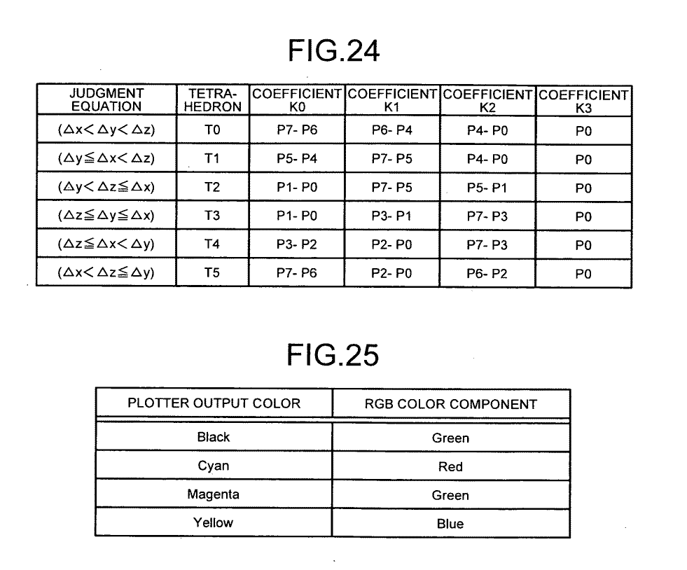

Then, the color conversion unit 53 obtains subordinate coordinates (Δx, Δy, Δz) of coordinates P in the selected unit cube shown in FIG. 22, and selects a unit cube by comparison in magnitude of the subordinate coordinates; and then performs linear interpolation on each of the unit cubes, thereby obtaining an output value Pout at the coordinates P. Incidentally, Pout is set to an integral value by multiplying the whole equation by the length of a side of the unit cube. FIGS. 23A to 23F are diagrams showing tetrahedrons into which the unit cube shown in FIG. 22 is divided, respectively. FIG. 24 is a diagram showing a rule for determining an interpolation coefficient of each tetrahedron. Incidentally, interpolation coefficients K0, K1, K2, and K3 are determined according to a magnitude relation of Δx, Δy, Δz and a separation signal described above.

Then, the color conversion unit 53 finally performs linear interpolation by equations (7-1) to (7-4) on the basis of preset output values on four vertices of the selected tetrahedron and location of input in the tetrahedron (a distance from each vertex).

pout_{—}c=K0_{—}C×Δx+K1_{—}C×Δy+K2_{—}C×Δz+K3_{—}C<<5 (7-1)

pout_{—}m=K0_{—}M×Δx+K1_{—}M×Δy+K2_{—}M×Δz+K3_{—}M<<5 (7-2)

pout_{—}y=K0_{—}Y×Δx+K1_{—}Y×Δy+K2_{—}Y×Δz+K3_{—}Y<<5 (7-3)

pout_{—}k=K0_{—}K×Δx+K1_{—}K×Δy+K2_{—}K×Δz+K3_{—}K<<5 (7-4)

Subsequently, the correction performed by the gamma correction unit 56 of the output-image processing unit 7 is explained specifically.

In the preview display operation, the gamma correction unit 56 converts the RGB image data into a device-independent signal which is independent of a variation of the plotter 9. Here, there is described a case of using one of RGB color components used as ACC target data for copy explained in the calibration operation described above.

The gamma correction unit 56 performs, as the color conversion, normal gamma correction with respect to a CMYK signal; however, a gamma table used in the gamma correction is the one that is generated by the CPU 4 in the calibration operation described above. Incidentally, in the present embodiment, a one-dimensional table is used, so an RGB color component is set with respect to each of CMYK color data as shown in FIG. 25; alternatively, it can be configured to target a plurality of color components by using a multidimensional table.

Then, the RGB value converted by the gamma correction unit 56 corresponds to a target density characteristic of printer gamma subject to calibration which varies according to an image output condition of the plotter 9 (the top density or a characteristic of a recording sheet), so it is possible to convert it into a color image signal corresponding to an image forming condition.

The gamma correction unit 56 further converts a combination of color data reflecting the target density characteristic of the calibration into a tristimulus value (CIEXYZ) which is a standard color system (see an arrow 114 in FIG. 20). Specifically, the gamma correction unit 56 obtains a correspondence between a typical combination of color plates (CMYK) and a colorimetric value (CIEXYZ) in advance and approximates it to a combination of color data, and converts the combination of color data into a tristimulus value using multidimensional LUT, nonlinear masking, neural network, or the like. Incidentally, an input value of each color plate (CMYK) is controlled not by device CMYK but by a device-independent signal based on a colorimetric value; in the present embodiment, the color control is performed by using one of RGB color components as described above.

Furthermore, here, a characteristic of a recording sheet as shown in FIG. 8 is reflected. In the present embodiment, the characteristic of a recording sheet corresponds to above-described B_Det, which is a value of a ground portion (the 0th level) of an ACC read value, and Acc_T0, which is a value of a ground portion (the 0th level) of ACC target data. When a user sets exact white color of a recording sheet as a white point as a condition of a preview display through the operation display unit 12, B_Det, a value of a ground portion of an ACC read value, is read out and converted into a tristimulus value (CIEXYZ).

Incidentally, B_Det is RGB into which a read value is color-converted, so if RGB is assumed to be sRGB, the color conversion into a tristimulus value (CIEXYZ) is expressed by equations (8-1) to (9-3).

r=(R/1023)^{2.2} (8-1)

g=(G/1023)^{2.2} (8-2)

b=(B/1023)^{2.2} (8-3)

X=0.4124×r+0.3576×g+0.1805×b (9-1)

Y=0.2126×r+0.7152×g+0.0722×b (9-2)

Z=0.0193×r+0.1192×g+0.9505×b (9-3)

Then, the gamma correction unit 56 converts the image signal converted into the tristimulus value (CIEXYZ) into a perception amount (JCH) for predicting color appearance under an observation condition (see an arrow 116 in FIG. 20). Specifically, the gamma correction unit 56 sets the converted tristimulus value (CIEXYZ) of the ground of the recording sheet (white color) as a tristimulus value (Xw, Yw, Zw) of reference white color defined in a color appearance model (CIECAM) recommended by the CIE, and converts a tristimulus value (CIEXYZ) into a perception amount (JCH) by performing processing of equations (10) to (39).

Incidentally, when a user has set the following property with respect to white color of a recording sheet through the operation display unit 12 at the time of execution of calibration or display of a preview image, the gamma correction unit 56 converts the ground-corrected read value Acc_Scn_k′ described in the ground correction in the calibration operation into a tristimulus value (CIEXYZ); sets the tristimulus value (CIEXYZ) as reference white color; and then performs the same color conversion process.

Furthermore, in the present embodiment, calculation is performed with a test color (X, Y, Z) as a tristimulus value of an image signal input from the scanner 1 and a reference white color (Xw, Yw, Zw) as a tristimulus value of the ground of a recording sheet (white color) (calculated from an ACC read value).

$$\begin{matrix} [ \begin{matrix}R \\ G \\ B\end{matrix} ] = [ {M}_{B} ] [ \begin{matrix}X / Y \\ 1 \\ Z / Y\end{matrix} ] & ( 10 ) \\ [ \begin{matrix}{R}_{W} \\ {G}_{W} \\ {B}_{W}\end{matrix} ] = [ {M}_{B} ] [ \begin{matrix}{X}_{W} / {Y}_{W} \\ 1 \\ {Z}_{W} / {Y}_{W}\end{matrix} ] & ( 11 ) \\ [ {M}_{B} ] = [ \begin{matrix}0.8951 & 0.2664 & - 0.1614 \\ - 0.7502 & 1.7135 & 0.0367 \\ 0.0369 & - 0.0685 & 1.0296\end{matrix} ] & ( 12 ) \\ Rc = ( D * ( 1.0 / Rw ) + 1 - D ) * R & ( 13 \text{-} 1 ) \\ Gc = ( D * ( 1.0 / Gw ) + 1 - D ) * G & ( 13 \text{-} 2 ) \\ If B < 0 , \\ Bc = ( D * ( 1.0 / pow ( Bw , p ) ) + 1 - D ) * fabs ( pow ( B , p ) ) * ( - 1.0 ) & ( 13 \text{-} 3 )\end{matrix}$$

If B≧0,

Bc=(D*(1.0/pow(Bw,p))+1−D)*pow(B,p) (13-4)

Rcw=(D*(1.0/Rw)+1−D)*Rw (14-1)

Gcw=(D*(1.0/Gw)+1−D)*Gw (14-2)

Bcw=(D*(1.0/pow(Bw,p))+1−D)*pow(fabs(Bw),p) (14-3)

However, p is calculated by equation (15), and D is calculated by equation (16).

p=pow((Bw/1.0),0.0834) (15)

D=F−F/(1+2*pow(La,1/4)+La*La/300) (16)

Here, La denotes the luminance of the adaptation visual field, and F denotes a coefficient representing a degree of adaptation. Incidentally, a D factor (a coefficient representing a degree of adaptation) defined here is basically calculated by equation (16); however, when a user has set a D factor as a parameter of the following property with respect to white color of a recording sheet through the operation display unit 12 at the time of execution of calibration or display of a preview image, the set parameter is reflected in a D factor.

$$\begin{matrix}[ \begin{matrix}{R}_{d} \\ {G}_{d} \\ {B}_{d}\end{matrix} ] = [ {M}_{H} ] [ {M}_{B}^{- 1} ] [ \begin{matrix}{R}_{C} / Y \\ {G}_{C} \\ {B}_{C} / Y\end{matrix} ] & ( 17 ) \\ [ \begin{matrix}{R}_{dW} \\ {G}_{dW} \\ {B}_{dW}\end{matrix} ] = [ {M}_{H} ] [ {M}_{B}^{- 1} ] [ \begin{matrix}{R}_{CW} / {Y}_{W} \\ {G}_{CW} \\ {B}_{CW} / {Y}_{W}\end{matrix} ] & ( 18 ) \\ [ {M}_{H} ] = [ \begin{matrix}0.38971 & 0.68898 & - 0.07868 \\ - 0.22981 & 1.18340 & 0.04641 \\ 0.00000 & 0.00000 & 1.00000\end{matrix} ] & ( 19 ) \\ Rda = \frac{( 40 * pow ( ( F 1 * Rd / 100 ) , 0.73 ) )}{( pow ( ( F 1 * Rd / 100 ) , 0.73 ) + 2 ) + 1} & ( 20 \text{-} 1 ) \\ Gda = \frac{( 40 * pow ( ( F 1 * Gd / 100 ) , 0.73 ) )}{( pow ( ( F 1 * Gd / 100 ) , 0.73 ) + 2 ) + 1} & ( 20 \text{-} 2 ) \\ Bda = \frac{( 40 * pow ( ( F 1 * Bd / 100 ) , 0.73 ) )}{( pow ( ( F 1 * Bd / 100 ) , 0.73 ) + 2 ) + 1 Rdaw} & ( 20 \text{-} 3 ) \\ Rdaw = \frac{( 40 * pow ( ( F 1 * Rdw / 100 ) , 0.73 ) )}{( pow ( ( F 1 * Rdw / 100 ) , 0.73 ) + 2 ) + 1} & ( 21 \text{-} 1 ) \\ Gdaw = \frac{( 40 * pow ( ( F 1 * Gdw / 100 ) , 0.73 ) )}{( pow ( ( F 1 * Gdw / 100 ) , 0.73 ) + 2 ) + 1} & ( 21 \text{-} 2 ) \\ Bdaw = \frac{( 40 * pow ( ( F 1 * Bdw / 100 ) , 0.73 ) )}{( pow ( ( F 1 * Bdw / 100 ) , 0.73 ) + 2 ) + 1} & ( 21 \text{-} 3 )\end{matrix}$$

However, F1 denoting a coefficient according to the adaptation luminance is calculated by equation (22).

F1=0.2*pow(k,4)*(5*La)+0.1*(1−pow(k,4))*(1−pow(k,4))*pow(5*La,1/3) (22)

Furthermore, k is calculated by equation (23).

k=1/(5*La+1) (23)

Then, A denoting an achromatic response is calculated by equation (24-1); Aw denoting an achromatic response with respect to white color is calculated by equation (24-2); J denoting the lightness is calculated by equation (25); Q denoting the brightness is calculated by equation (26); s denoting the saturation is calculated by equation (27); C denoting the chroma is calculated by equation (28); M denoting the colorfulness is calculated by equation (29).

A=(2*Rda+Gda+(1/20)*Bda−2.05)*Nbb (24-1)

Aw=(2*Rdaw+Gdaw+(1/20)*Bdaw−2.05)*Nbb(24-2)

J=100*pow(A/Aw,c*z) (25)

Q=(1.24/c)*pow((J/100),0.67)*pow((Aw+3),0.9) (26)

s=(50*pow((a*a+b*b),0.5)*100*e*(10/13)*Nc*Ncb)/(Rda+Gda+(21/20)*Bda) (27)

C=2.44*pow(s,0.69)*pow((J/100),0.67*n)*(1.64−pow(0.29,n)) (28)

M=C*pow(F1,0.15) (29)

Here, c denotes a coefficient relating to the magnitude of environmental influence, and Nc denotes a chromatic induction coefficient. Furthermore, n denoting a coefficient representing a degree of how the background affects the appearance of a stimulus is calculated by equation (30); Nbb is calculated by equation (31); Ncb is calculated by equation (32); z is calculated by equation (33).

n=Yb/Yw (30)

Nbb=0.725*pow(1/n,0.2) (31)

Ncb=Nbb (32)

z=1+F11*pow(n,0.5) (33)

Incidentally, Yb denotes a luminance factor of the background, and F11 denotes a lightness contrast coefficient.

Moreover, e is calculated by equations (34) to (39).

Ca=Rda−12.0*Gda/11.0+Bda/11.0 (34)

Cb=(1/9)*(Rda+Gda−2*Bda) (35)

h=(180/M_{—}PI)*a tan 2(b,a) (36)

However,if h<0,h=360−fabs(h) (37)

e=e1+(e2−e1)*(h−h1)/(h2−h1) (38)

H=h1+100*(h−h1)/e1/((h−h1)/e1+(h2−h)/e2) (39)

However, if h≦20.14, e1=0.8565, e2=0.8, h1=0.0, and h2=20.14; if 20.14<h≦90.0, e1=0.8, e2=0.7, h1=20.14, and h2=90.0; if 90.0<h≦164.25, e1=0.7, e2=1.0, h1=90.0, and h2=164.25; if 164.25<h≦237.53, e1=1.0, e2=1.2, h1=164.25, and h2=237.53; if 237.53<h, e1=1.2, e2=0.8565, h1=237.53, and h2=360.0.

Incidentally, in the present embodiment, when the gamma correction unit 56 converts a tristimulus value (CIEXYZ) into a perception amount (JCH) by performing processing of equations (10) to (39), various parameters indicating observation conditions responding to an actual environment to observe a hard copy are set by a user through the operation display unit 12 (see an arrow 118 in FIG. 20).

However, if no hard-copy observation condition is set by a user, in accordance with the definition of RGB (sRGB), it is set as follows: La=4(cd/m²), F=1.0 (Average), Yb=20, F11=1.0 (Average), c=0.69 (Average), and Nc=1.0 (Average).

Then, before converting the obtained image data of which the color is converted into the perception amount (JCH) based on the color appearance model into an RGB signal for display, the gamma correction unit 56 converts the image data into a tristimulus value (CIEXYZ) again (see an arrow 120 in FIG. 20). Specifically, the gamma correction unit 56 performs inverse transform of equations (10) to (39). Incidentally, at this time, the observation conditions of the operation display unit 12 shown in FIG. 20 are reflected.

However, if no preview-display observation condition is set by a user, in accordance with the definition of uniform RGB, it is set as follows: Xw=95.02, Yw=100, Zw=108.81 (D65 light source), La=4 (cd/m²), F=1.0 (Average), Yb=20, F11=1.0 (Average), c=0.69 (Average), and Nc=1.0 (Average).

Then, the gamma correction unit 56 converts a test color (X, Y, Z) obtained by the inverse operation into an RGB signal for preview display (see an arrow 122 in FIG. 20). For example, if it is assumed that a characteristic of the operation display unit 12 is sRGB, it can be converted into RGB image data by performing the inverse operation of equations (8-1) to (9-3); alternatively, the conversion can be performed with reference to a profile of a display device of an external apparatus acquired via the external I/F 14.

Then, the finally-color-converted RGB image signal for preview display is transmitted to the operation display unit 12 or the PC 22, and displayed on a high-definition display with the color management. This allows the operation display unit 12 or the PC 22 to faithfully display a preview of not only the finish of an image corresponding to an image output condition but the color appearance of the image under an environment to actually observe the image output onto a recording sheet on the display; therefore, the color adjustment, including the setting of an image output mode according to a state of the actual apparatus and an image output request from a user and the setting of an optimum calibration condition, can be made.

Furthermore, when an attribute of the RGB signal for preview display is instructed to be changed from a user through the operation display unit 12, a conversion from the tristimulus value (CIEXYZ) into RGB image data is performed on the basis of a relation between the specified RGB color space and the tristimulus value (CIEXYZ).

For example, a color reproduction characteristic of the display for preview display conforms to sRGB, a color reproduced in a hard copy may not be able to be reproduced in the sRGB color space (0 to 1). This is a case where a color tone of a high-saturation portion of an output image is not displayed properly; in this case, by setting to the RGB color space having a wider color gamut than sRGB depending on the intended use, the color adjustment, including the setting of an image output mode according to an image output request from a user and the setting of an optimum calibration condition, can be made.

For example, when a user sets the RGB color space defined as a DCF option color space for preview display through the operation display unit 12, the color conversion to RGB for preview display is performed by a color conversion indicated in equations (40-1) to (41-3).

rp=2.0148*X−0.6217*Y−0.3931*Z (40-1)

gp=−1.2883*X+2.2360*Y+0.0523*Z (40-2)

bP=0.0174*X−0.2055*Y+1.1881*Z (40-3)

Rp=((rp)̂(1/2.2))*1023 (41-1)

Gp=((Gp)̂(1/2.2))*1023 (41-2)

Bp=((Bp)̂(1/2.2))*1023 (41-3)

### 2-4. Color Adjustment Operation

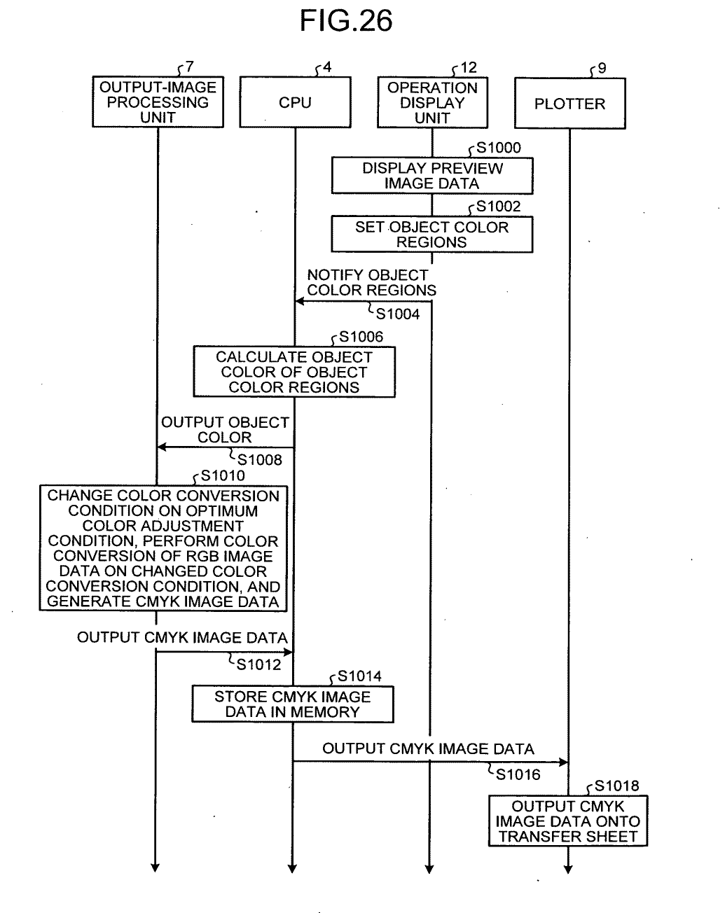

Subsequently, color adjustment operation of the MFP according to the present embodiment, particularly, color adjustment operation for adjusting color unevenness of an area of output image data specified by a user through preview image data displayed in the preview display operation is explained. FIG. 26 is a sequence diagram showing an example of a flow of procedures of the color adjustment operation performed by the MFP 100 according to the present embodiment.

As described in the preview display operation shown in FIG. 19, the operation display unit 12 (an example of a display unit, a color-region input unit, and a target-color input unit) displays preview image data which is image data that a characteristic of an image output device and an observation condition are reflected in RGB image data generated by the scanner 1 (an example of an image generating unit) (Step S1000). Then, the operation display unit 12 receives settings of a plurality of object color regions subject to color matching from a user through the displayed preview image data (Step S1002), and notifies the CPU 4 of the settings of the object color regions (i.e., inputs the settings of the object color regions to the CPU 4) (Step S1004, see arrow 132 in FIG. 20).

Then, the CPU 4 (an example of a target-color calculating unit) calculates an object color subject to color matching by averaging RGB values of all pixels contained in the notified object color regions on a component-by-component basis (Step S1006), and outputs the calculated object color to the output-image processing unit 7 via the bus control unit 3 (Step S1008, see arrow 134 in FIG. 20).

Then, the color-adjustment-condition setting unit 51 of the output-image processing unit 7 converts the RGB image data generated by the scanner 1 into a perception amount in a perceptual color space to be described later, and obtains (a combination of) a plurality of color adjustment conditions capable of keeping the color within an allowable color difference in the perceptual color space on the basis of a correction of a difference in three attributes of color (lightness, saturation, hue). The color-conversion-condition changing unit 52 of the output-image processing unit 7 calculates an effect of the correction of the three attributes of color (lightness, saturation, hue) on the entire color space from an output difference with respect to a representative color in the input color space or a representative color in an input (read) image. Then, the color-conversion-condition changing unit 52 changes a color conversion condition of the color conversion unit 53 on an optimum color adjustment condition of the specified object color under an output condition or an observation environment.

The color conversion unit 53 of the output-image processing unit 7 performs a color conversion of the RGB image data on the changed color conversion condition, and generates CMYK image data (Step S1010). Then, the output-image processing unit 7 outputs the generated CMYK image data to the CPU 4 via the bus control unit 3 (Step S1012).

Then, the CPU 4 stores the CMYK image data in the memory 5 (Step S1014), and outputs the CMYK image data stored in the memory 5 to the plotter 9 via the plotter I/F 8 (Step S1016).

Then, the plotter 9 (an example of an image output unit) outputs the CMYK image data onto a transfer sheet and generates a copy of an original (Step S1018).

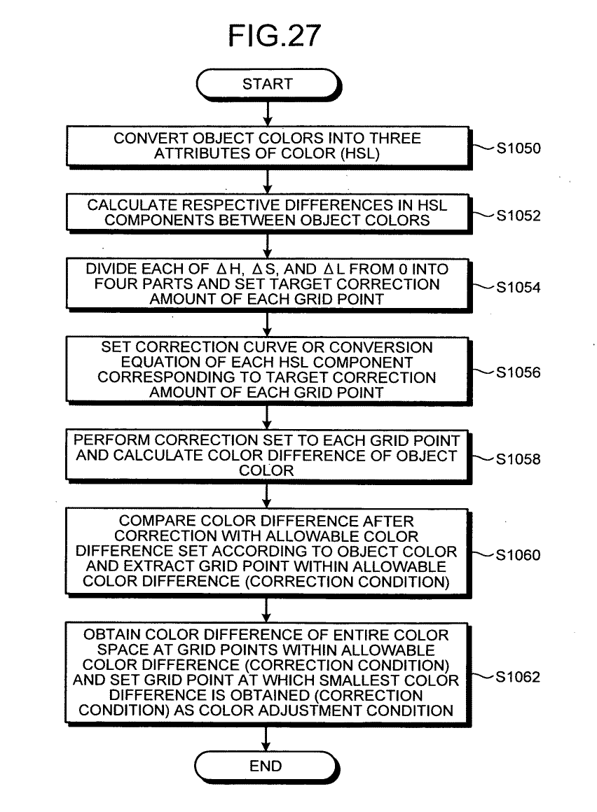

FIG. 27 is a flowchart showing an example of a flow of procedures of a color adjustment process performed by the output-image processing unit 7 according to the present embodiment.

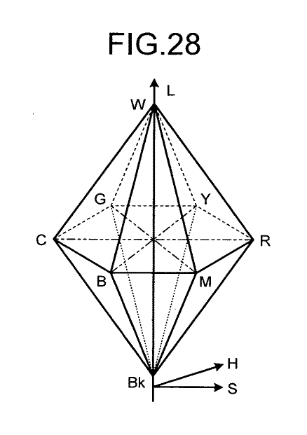

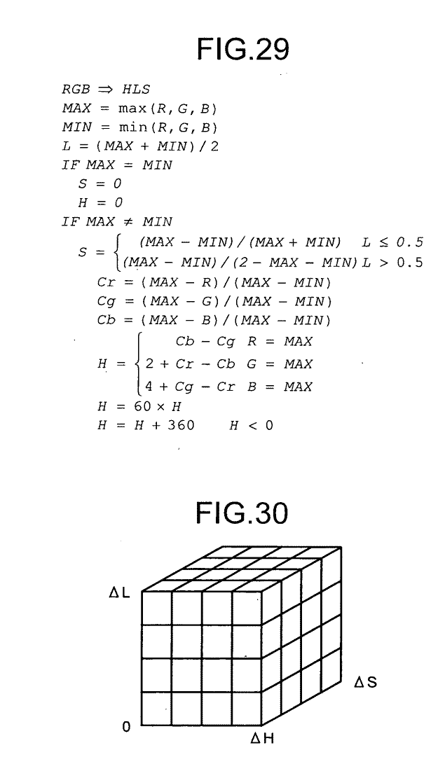

First, the color-adjustment-condition setting unit 51 converts RGB values of a plurality of object colors calculated by the CPU 4 into data of the HSL color system indicating three attributes of color (hue, saturation, lightness) (Step S1050). Incidentally, in the present embodiment, the color space of the HSL color system is assumed to be a hexahedral bipyramid color system based on the Ostwald color system as shown in FIG. 28, and the color-adjustment-condition setting unit 51 converts RGB values of a plurality of object colors into data of the HSL color system using conversion equations shown in FIG. 29.

Then, the color-adjustment-condition setting unit 51 calculates respective differences in HSL components (ΔH, ΔS, ΔL) between object colors (H1S1L1, H2S2L2) in a plurality of regions (for example, two regions) subject to color matching by using equations (42-1) to (42-3) (Step S1052).

ΔH=|H1−H2| (42-1)

ΔS=|S1−S2| (42-2)

ΔL=|L1−L2| (42-3)

Incidentally, when a different target color (H0S0L0) with respect to the object colors (H1S1L1, H2S2L2) has been set (input) by a user through the operation display unit 12, the color-adjustment-condition setting unit 51 calculates respective differences in HSL components between the target color and each of the object colors by using equations (43-1) to (43-6), and calculates a maximum correction amount.

ΔH1=|H0−H1| (43-1)

ΔS1=|S0−S1| (43-2)

ΔL1=|L0−L1| (43-3)

ΔH2=|H0−H2| (43-4)

ΔS2=|S0−S2| (43-5)

ΔL2=|L0−L2| (43-6)

Then, with any of the object colors as a reference color, the color-adjustment-condition setting unit 51 divides each of the components ΔH, ΔS, and ΔL from a reference color 0 into four parts as shown in FIG. 30, and sets a target correction amount of each grid point (Step S1054). Incidentally, when a target color has been set, the color-adjustment-condition setting unit 51 creates cubes shown in FIG. 30 corresponding to the number of regions (for example, two cubes).

Then, the color-adjustment-condition setting unit 51 sets a correction curve or conversion equation, which is achieved by a one-dimensional input-output conversion table or the like, of each HSL component corresponding to a target correction amount of each grid point (Step S1056).

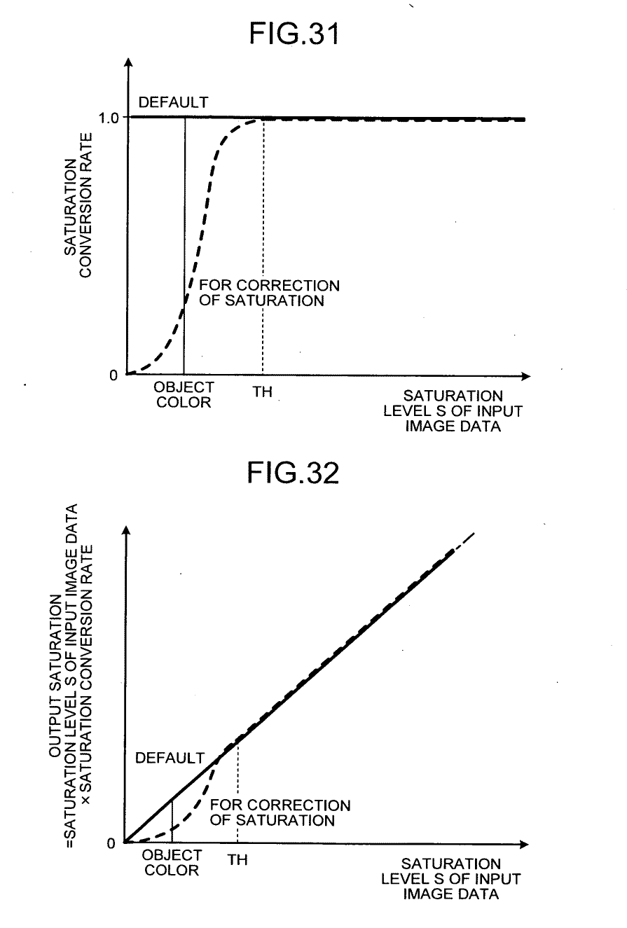

FIGS. 31 and 32 are diagrams each showing an example of a color adjustment condition (for correction of an S value (the saturation)) for reducing a difference (reducing the color unevenness) when a color around achromatic color is an object color. The saturation correction condition shown in FIGS. 31 and 32 is for causing the color-adjustment-condition setting unit 51 to perform a process for nonlinearly reducing the saturation (perform compression of the saturation) with respect to input of which the saturation S of the input color is equal to or lower than a predetermined level TH; if this is applied to the object color in the present operation example, when a target color is an achromatic color (saturation: S=0), the saturation correction condition is a color adjustment condition corresponding to one grid point shown in FIG. 30 to which a target correction amount is set.

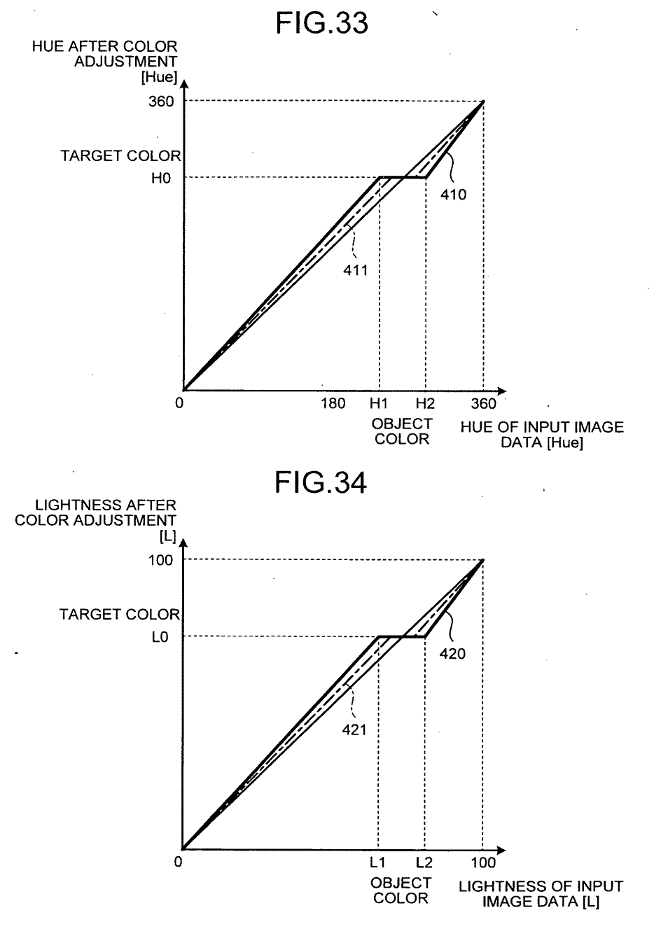

FIG. 33 is a diagram showing an example of a color adjustment condition for correction of the hue (an H value). The hue correction condition shown in FIG. 33 is for causing the color-adjustment-condition setting unit 51 to perform a process for linearly correcting the hue if a target color is set. Here, an ultimate correction condition to match a hue component of an object color to a target color is a characteristic indicated by a bold line 410 in FIG. 33, and corresponds to a correction condition with respect to a vertex of the cube in a direction of ΔH with respect to the origin of the cube shown in FIG. 30 (no correction to a hue component). Therefore, a correction condition corresponding to a grid point located midway in between them in the direction of ΔH is an interval linear correction indicated by a broken line 411 in FIG. 33.

FIG. 34 is a diagram showing an example of a color adjustment condition for correction of the lightness (an L value). The hue correction condition shown in FIG. 34 is for causing the color-adjustment-condition setting unit 51 to perform a process for linearly correcting the lightness if a target color is set. Here, an ultimate correction condition to match a lightness component of an object color to a target color is a characteristic indicated by a bold line 420 in FIG. 34, and corresponds to a correction condition with respect to a vertex of the cube in a direction of ΔL with respect to the origin of the cube shown in FIG. 30 (no correction to a hue component). Therefore, a correction condition corresponding to a grid point located midway in between them in the direction of ΔL is an interval linear correction indicated by a broken line 421 in FIG. 34.

Then, the color-adjustment-condition setting unit 51 performs the correction to each color component with reference to the correction condition set to each grid point at Step S1056, and calculates a color difference of the object color (Step S1058). Incidentally, in an example where a target color is set and the color-adjustment-condition setting unit 51 performs the linear correction process, performed is the conversion into CMYK, output colors of the plotter 9, by the color conversion unit 53 of the output-image processing unit 7 as described above in the preview display operation on each of the colors (H1S1L1, H2S2L2, H0S0L0). Then, the color-adjustment-condition setting unit 51 calculates a perception amount (JCH or JCaCa, in the present operation example) under an image output condition, and calculates a Euclidean distance in the converted color space. Specifically, the color-adjustment-condition setting unit 51 calculates: ΔE1, which is a Euclidean distance between the object color (H1S1L1) and the target color (H0S0L0) in the perceptual color space; and ΔE2, which is a Euclidean distance between the object color (H2S2L2) and the target color (H0S0L0) in the perceptual color space.

Then, the color-adjustment-condition setting unit 51 compares a color difference after the correction with an allowable color difference set according to the object color, and extracts a grid point within the allowable color difference (a correction condition) (Step S1060, see an arrow 136 in FIG. 20). Incidentally, in an example where a target color is set and the linear correction process is performed, the color-adjustment-condition setting unit 51 compares respective color differences (ΔE1 and ΔE2) between the object colors and the target color with an allowable color difference (ΔEcmc) with respect to each object color, and extracts a grid point meeting a condition of equation (44) (a condition of color correction with respect to the three attributes of color).

(ΔEcmc≦ΔE1)̂(ΔEcmc≦ΔE2) (44)

Here, the allowable color difference (ΔEcmc) is corrected by the color-adjustment-condition setting unit 51 based on the coordinates of the set object color in the color space under an image output condition and based on a position relation of a color region set in an input image; and the corrected allowable color difference (ΔEcmc) is set by the color-adjustment-condition setting unit 51. Specifically, with an average value of the object color (RGB) as input (In_R, In_G, In_B), the color-adjustment-condition setting unit 51 obtains subordinate coordinates (Δx, Δy, Δz) of coordinates P in the selected unit cube using the above-described three-dimensional memory map interpolation. Then, the color-adjustment-condition setting unit 51 selects a unit tetrahedron by comparison in magnitude of the subordinate coordinates, and performs linear interpolation on each of the unit tetrahedrons, thereby obtaining an output value Pout at the coordinates P. Here, with P0 to P7 in FIG. 22 as grid-point output values, the color-adjustment-condition setting unit 51 obtains an allowable color difference corresponding to a grid point (RGB coordinates) by an evaluation experiment or the like and sets the obtained allowable color difference in advance. Furthermore, the color-adjustment-condition setting unit 51 further corrects an allowable color difference (ΔEcmc), which has been corrected according to the coordinates in the color space, according to a position relation of a color region set in an input image. For example, the color-adjustment-condition setting unit 51 extracts a combination of coordinates (X1Y1, X2Y2) in which a distance between them is smallest based on a difference of the input coordinates (XY) of the color region (four points of a rectangle) set as an object color with respect to preview image data by a user through the operation display unit 12, and corrects the allowable color difference by equation (45) and sets the corrected allowable color difference as a final allowable color difference (ΔEcmch).

ΔEcmch=ΔEcmc+α×sqrt((X2−X1)²+(Y2−Y1)²) (45)

Incidentally, α is a coefficient set according to the coordinates in the color space.

Then, the color-conversion-condition changing unit 52 obtains a color difference of the entire color space at grid points within the allowable color difference (a correction condition), and selects one of the grid points at which the smallest color difference is obtained (a correction condition) as a color adjustment condition (Step S1062, see an arrow 138 in FIG. 20). Also, here, the color-conversion-condition changing unit 52 performs the conversion into CMYK, output colors of the plotter 9, by the color conversion unit 53 of the output-image processing unit 7 as described above in the preview display operation with respect to a representative color in the uniform color space and a plurality of colors contained in the input image. Then, the color-conversion-condition changing unit 52 calculates a perception amount (JCH or JCaCa, in the present operation example) of each evaluated color under an image output condition, and averages the color differences before and after the correction on the correction condition (with respect to the three attributes of color) within the allowable color difference obtained at Step S1062 by weighted average, and selects a grid point at which the smallest color difference is obtained (a correction condition) as a color adjustment condition.

Incidentally, the color adjustment condition (a saturation component, a hue component, a lightness component) obtained by the color-conversion-condition changing unit 52 at Step S1062 is reflected according to a color correction process flow. Before conversion into control data of the output device by the color conversion unit 53, the color-conversion-condition changing unit 52 can convert image data into the HSL color space (see FIG. 30) and perform the above-described component-by-component correction on each pixel of the image data or can reflect the color adjustment condition in a parameter of the color space conversion (the three-dimensional LUT) performed by the color conversion unit 53, i.e., a profile of the image input/output device (a color conversion value of the 3DLUT). The color conversion unit 53 performs color conversion using the parameter into which the color adjustment condition is reflected by the color-conversion-condition changing unit 52.

As described above, in the present embodiment, a plurality of color adjustment conditions capable of keeping output of an object color under an image output condition within an allowable color difference is set; one of the color adjustment conditions on which a color difference occurring in the entire color space is smallest is selected; a color conversion condition is changed; and then color conversion of image data is performed on the changed color conversion condition. Therefore, according to the present embodiment, it is possible to reduce color unevenness in an output image while maintaining the faithful color reproduction as much as possible. Namely, the specified color in an output image can be matched (i.e., color unevenness can be reduced) according to characteristics of the image input/output device and the nature of an input image without distorting the color space significantly (while maintaining the faithful color reproduction as much as possible). As a result, color unevenness in an output image due to a variation in spectral characteristics of color filters in an image reading device using a CIS or the like can be improved without performing complicated real-time processing.

Furthermore, in the present embodiment, a plurality of color adjustment conditions are calculated on the basis of correction to the three attributes of color; therefore, the specified color in an output image can be matched (i.e., color unevenness can be reduced) without distorting the color space significantly on a color adjustment condition meeting human color perception characteristics.

Moreover, in the present embodiment, amplitude of allowable color difference is corrected according to coordinates of an object color in the color space under an image output condition; therefore, by using an allowable color difference reflecting a result of detailed visual evaluation, the specified color in an output image can be matched (i.e., color unevenness can be reduced) while suppressing distortion of the color space (while maintaining the faithful color reproduction as much as possible).

Furthermore, in the present embodiment, amplitude of allowable color difference is corrected according to a position relation of color regions; therefore, for example, by using an allowable color difference reflecting a human color perception characteristic that a difference of adjacent colors is easily recognized, the specified color in an output image can be matched (i.e., color unevenness can be reduced) while suppressing distortion of the color space (while maintaining the faithful color reproduction as much as possible).

Moreover, in the present embodiment, a user can input a color region subject to color matching through a preview image reflecting an image output condition or an observation condition; therefore, by setting an object color based on evaluation of a difference of colors under an actual observation environment, the specified color in an output image can be matched (i.e., color unevenness can be reduced) while suppressing distortion of the color space (while maintaining the faithful color reproduction as much as possible).

Furthermore, in the present embodiment, an image output condition is corrected on the basis of a perception amount indicating appearance of color based on the color appearance model; therefore, by setting an object color based on evaluation of a difference of colors under an actual observation environment which can be relatively easily made without using information on spectral characteristics, the specified color in an output image can be matched (i.e., color unevenness can be reduced) while suppressing distortion of the color space (while maintaining the faithful color reproduction as much as possible).

Modification

Incidentally, the present invention is not limited to the above embodiment, and various variations can be made. For example, the color adjustment described above can be realized as software for a color printer by causing the CPU or the like to execute a color adjustment program.

In this case, the color adjustment program is stored in a computer-readable recording medium, such as a CD-ROM, a CD-R, a memory card, a digital versatile disk (DVD), or a flexible disk (FD), in an installable or executable file format, and the recording medium is provided.

Furthermore, the color adjustment program can be stored on a computer connected to a network such as the Internet, and the color adjustment program can be provided by causing a user to download it via the network. Moreover, the color adjustment program can be provided or distributed via a network such as the Internet. Furthermore, the color adjustment program can be built into the ROM or the like in advance.

The color adjustment program is composed of modules for realizing the above-described units (the color-adjustment-condition setting unit 51, the color-conversion-condition changing unit 52, the color conversion unit 53, and the like) on a computer. The CPU as actual hardware loads the color adjustment program from the HDD onto the RAM, and executes the color adjustment program, thereby realizing the above-described units on the computer.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An image forming apparatus, comprising:
an image generating unit that reads an original and generates image data;
a color-region input unit that inputs a color region subject to color matching in the image data;
an object-color calculating unit that calculates an object color to which the color region is matched;
a color-adjustment-condition setting unit that sets a plurality of color adjustment conditions on which output of the object color under an image output condition is within an allowable color difference;
a color-conversion-condition changing unit
that selects one of the color adjustment conditions on, which a color difference occurring in an entire color space is smallest, and
that changes a color conversion condition;
a color conversion unit that performs color conversion of the image data based on the changed color conversion condition; and
an image output unit that outputs the image data subjected to the color conversion.

2. The image forming apparatus according to claim 1, further comprising
a target-color input unit that inputs a target color for the object color, wherein
the color-adjustment-condition setting unit sets a plurality of color adjustment conditions on which output of the object color under the image output condition is close to the target color.

3. The image forming apparatus according to claim 1, wherein
the color-adjustment-condition setting unit calculates the plurality of color adjustment conditions on the basis of correction to three attributes of color.

4. The image forming apparatus according to claim 1, wherein
the color-adjustment-condition setting unit corrects amplitude of the allowable color difference based on coordinates of the object color in the color space under the image output condition.

5. The image forming apparatus according to claim 1, wherein
the color-adjustment-condition setting unit corrects amplitude of the allowable color difference based on a position relation of the color region.

6. The image forming apparatus according to claim 1, wherein
the image forming apparatus displays a preview image of the image data generated by the image generating unit into which the image output condition or an observation condition of the image data output from the image output unit is reflected.

7. The image forming apparatus according to claim 1, wherein
the image output condition is corrected on the basis of a perception amount indicating appearance of color based on a color appearance model.

8. A color adjustment method, comprising:
reading an original and generating image data by an image generating unit;
inputting a color region subject to color matching in the image data by a color-region input unit;
calculating an object color to which the color region is matched by an object-color calculating unit;
setting a plurality of color adjustment conditions on which output of the object color under an image output condition is within an allowable color difference by a color-adjustment-condition setting unit;
selecting one of the color adjustment conditions on which a color difference occurring in an entire color space is smallest, and changing a color conversion condition by a color-conversion-condition changing unit;
performing color conversion of the image data based on the changed color conversion condition by a color conversion unit; and
outputting the image data subjected to the color conversion by an image output unit.

9. A computer program product comprising a non-transitory computer program product having computer-readable program codes embodied in the medium for color adjustment in an image forming apparatus, the program codes when executed causing a computer to execute:
calculating an object color to which a color region of image data of a read original is matched;
setting a plurality of color adjustment conditions on which output of the object color under an image output condition is within an allowable color difference;
selecting one of the color adjustment conditions on which a color difference occurring in an entire color space is smallest and changing a color conversion condition; and
performing color conversion of the image data based on the changed color conversion condition.
